(19) United States
(12) Patent Application Publication
(10) Pub. No.: US 2026/0353757 A1
(43) Pub. Date: Nov. 5, 2026

(54) INCORPORATING FLUORINE INTO COMPONENTS OF A TRANSISTOR

(71) Applicant: Taiwan Semiconductor Manufacturing Company, Ltd., Hsin-Chu (TW)

(72) Inventors: Shou-Wei Li, Taichung City (TW); Hsin-Yi Lee, Hsinchu City (TW); Chih-Wei Lee, New Taipei City (TW); Kuo-Feng Yu, Hsinchu County (TW)

(21) Appl. No.: 19/334,173

(22) Filed: Sep. 19, 2025

Related U.S. Application Data
(60) Provisional application No. 63/800,141, filed on May 5, 2025.

(51) Int. Cl. H10D 64/68; H10D 30/00; H10D 30/01; H10D 62/10; H10D 64/01; H10D 64/66

(52) U.S. Cl. CPC H10D 64/685; H10D 30/0191; H10D 30/502; H10D 64/0134; H10D 64/669; H10D 62/121

(57) ABSTRACT

A stack of silicon-containing nano-structure channels is disposed over one another in a vertical direction in a cross-sectional side view defined by the vertical direction and a first horizontal direction. Gate dielectric layers of a gate structure are disposed over the nano-structure channels. The gate dielectric layers circumferentially surround respective ones of the nano-structure channels in the cross-sectional side view. One of the gate dielectric layers has a first fluorine concentration level. A gate electrode structure of the gate structure is disposed over the gate dielectric layers and include a work function metal having a second fluorine concentration level lower than the first fluorine concentration level. In a top view defined by the first horizontal direction and a second horizontal direction different from the first horizontal direction, the gate electrode structure extends in the first horizontal direction. At least one of the nano-structure channels extends in the second horizontal direction.

### PRIORITY DATA

The present application is a Utility Patent Application of Provisional U.S. Patent Application No. 63/800,141, filed on May 5, 2025, entitled “Incorporating fluorine in a high-k dielectric of a gate stack before formation of P/N/work function metals”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down has also increased the complexity of processing and manufacturing ICs. For example, as device sizes shrink, metal diffusion through boundaries between NFETs and PFETs may become exacerbated, which could lead to undesirable threshold voltage shifts. As a result, IC device performance and/or yield may be degraded.

Therefore, although conventional methods of fabricating semiconductor devices have generally been adequate, they have not been satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a perspective view of an IC device in the form of a FinFET according to various aspects of the present disclosure.

FIG. 1B is a planar top view of an IC device in the form of a FinFET according to various aspects of the present disclosure.

FIG. 1C is a cross-sectional side view of an IC device in the form of a GAA device according to various aspects of the present disclosure.

FIGS. 2A, 2B, and 2C are two different cross-sectional side views and a perspective three-dimensional view illustrating an IC device at a stage of fabrication according to various aspects of the present disclosure.

FIGS. 3A and 3B are different cross-sectional side views illustrating an IC device at a stage of fabrication according to various aspects of the present disclosure.

FIGS. 4A and 4B are different cross-sectional side views illustrating an IC device at a stage of fabrication according to various aspects of the present disclosure.

FIGS. 5A and 5B are different cross-sectional side views illustrating an IC device at a stage of fabrication according to various aspects of the present disclosure.

FIGS. 6A, 6B, and 6C are different cross-sectional side views illustrating an IC device at a stage of fabrication according to various aspects of the present disclosure.

FIGS. 7A, 7B, and 7C are different cross-sectional side views illustrating an IC device at a stage of fabrication according to various aspects of the present disclosure.

FIGS. 8A and 8B are different cross-sectional side views illustrating an IC device at a stage of fabrication according to various aspects of the present disclosure.

FIGS. 9A and 9B are different cross-sectional side views illustrating an IC device at a stage of fabrication according to various aspects of the present disclosure.

FIGS. 10A and 10B are different cross-sectional side views illustrating an IC device at a stage of fabrication according to various aspects of the present disclosure.

FIGS. 11A and 11B are different cross-sectional side views illustrating an IC device at a stage of fabrication according to various aspects of the present disclosure.

FIGS. 12A and 12B are different cross-sectional side views illustrating an IC device at a stage of fabrication according to various aspects of the present disclosure.

FIGS. 13A and 13B are different cross-sectional side views illustrating an IC device at a stage of fabrication according to various aspects of the present disclosure.

FIGS. 14A, 14B, 14C, and 14D are a cross-sectional side view and different top views illustrating an IC device at a stage of fabrication according to various aspects of the present disclosure.

FIGS. 15A, 15B, 15C, and 15D are various cross-sectional side views illustrating an IC device at a stage of fabrication according to various aspects of the present disclosure.

FIGS. 16A, 16B, and 16C are a perspective three-dimensional view and two cross-sectional side views illustrating an IC device at a stage of fabrication according to various aspects of the present disclosure.

FIGS. 17A, 17B, and 17C are a perspective three-dimensional view and two cross-sectional side views illustrating an IC device at a stage of fabrication according to various aspects of the present disclosure.

FIG. 18 is a top view illustrating an interconnect structure of an IC device at a stage of fabrication according to various aspects of the present disclosure.

FIG. 19 is a cross-sectional side view illustrating an IC device that includes an interconnect structure at a stage of fabrication according to various aspects of the present disclosure.

FIG. 20 is a block diagram of a manufacturing system according to various aspects of the present disclosure.

FIG. 21 is a flowchart illustrating a method of fabricating an IC device according to various aspects of the present disclosure.

FIG. 22 is a graph illustrating a fluorine distribution profile within an IC device according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm. However, other ranges are possible as known by those skilled in the art and may be process dependent.

The present disclosure is generally related to semiconductor devices, and more particularly to field-effect transistors (FETs), such as three-dimensional fin-shaped FETs (FinFETs) or gate-all-around (GAA) devices. In that regard, a FinFET device is a fin-like field-effect transistor device, and a GAA device is a multi-channel field-effect transistor device. FinFET devices and GAA devices have both been gaining popularity recently in the semiconductor industry, since they offer several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices or GAA devices for a portion of, or the entire IC chip.

However, despite the advantages offered by the FinFET devices and/or GAA devices, certain challenges may still remain in IC applications in which FinFET or GAA devices are implemented. For instance, in modern IC applications, the gate stacks of an an-type field effect transistor (NFET) and a p-type field effect transistor (PFET) may abut each other at a boundary. However, metal diffusion may occur through such a boundary. For example, metals (e.g., aluminum) in the gate stack of one type of transistors (e.g., the NFET) may diffuse across the boundary into the gate stack of another type of transistor (e.g., the PFET). Such a diffusion may be referred to as a metal boundary effect (MBE), and it may alter the intended work functions of these transistors. For example, the metal diffusion may change an absolute value of a threshold voltage of the NFET and/or change an absolute value of a threshold voltage of the PFET, which could then alter the intended functionality and/or performance of these transistors. As semiconductor device sizes continue to shrink, the threshold voltage shifts due to the MBE may become exacerbated (since the distances between the transistors also shrink), which may further degrade IC device performance and/or yield.

In order to reduce the MBE, fluorine may be incorporated into gate dielectrics of the gate stacks, which may increase an energy barrier needed for metals diffusion to occur. For example, the incorporation of fluorine in the gate dielectrics facilitates the passivation of bulk oxygen vacancies and the reduction of dangling bonds in the gate dielectric, which helps to increase barrier energy. As a result, leakage current is reduced, and threshold voltage stability is improved. However, if fabrication processes are not carefully configured, the fluorine in the gate dielectrics may not be uniformly distributed. For example, in the case of the GAA device, the fluorine may congregate mostly at side portions of gate dielectrics, but not in the portions of the gate dielectrics located directly above or below the nano-structure channels in a GAA device, which may lead to suboptimal device performance.

The present disclosure addresses these issues by incorporating fluorine in gate dielectrics before the formation of work function (WF) metals of a gate electrode. In particular, a base layer (e.g., containing titanium nitride) and a fluorine-containing layer (e.g., containing tungsten and fluorine) may be formed on the gate dielectric, where the fluorine-containing layer also has a fluorine source. The fluorine-containing layer is then annealed to drive the fluorine into the gate dielectric. Thereafter, the base layer and the fluorine-containing layer are removed, and then a metal-containing gate electrode is formed. Such a unique fabrication process flow leads to a more uniform distribution of fluorine in the gate dielectric, including in portions of the gate dielectric disposed directly between nano-structure channels of a GAA device. The various aspects of the present disclosure will now be discussed in greater detail below.

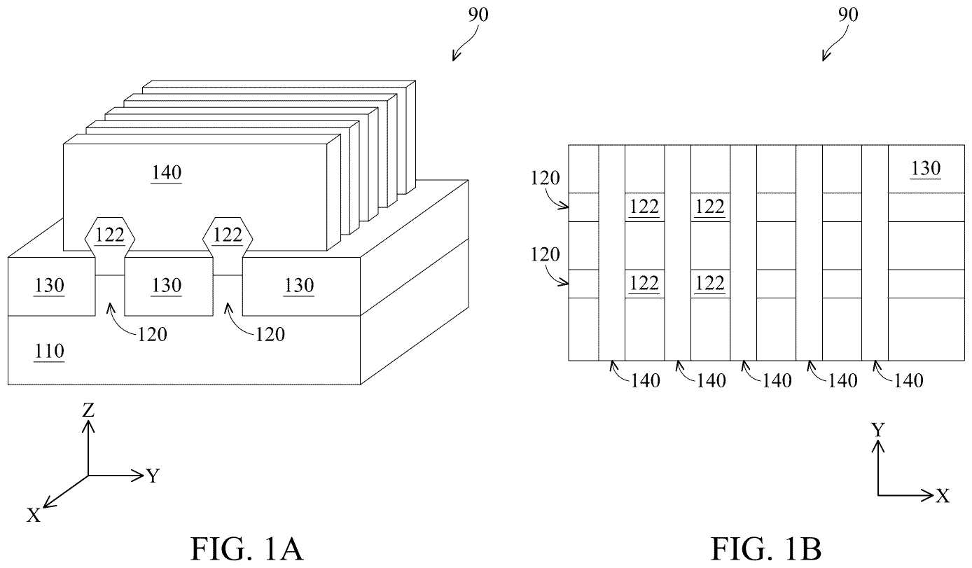

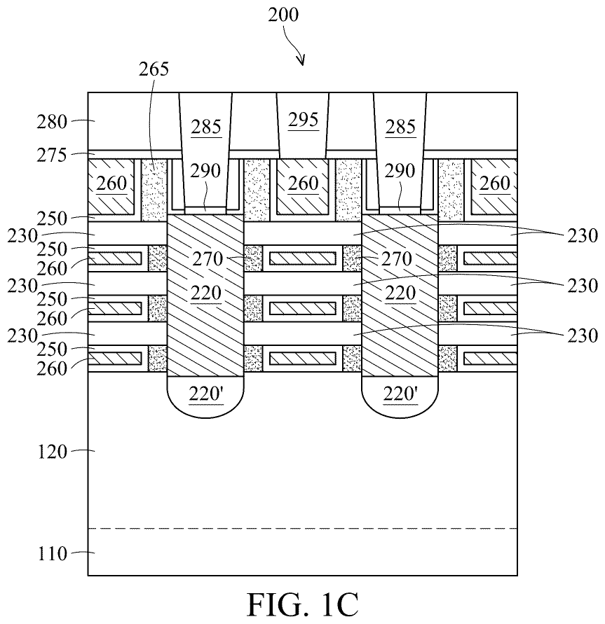

FIGS. 1A-1C describe the basic structures of example FinFET and GAA devices. Referring now to FIGS. 1A and 1B, a three-dimensional perspective view and a top view of a portion of an Integrated Circuit (IC) device 90 are illustrated, respectively. The IC device 90 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. The present disclosure is not limited to any particular number of devices or device regions, or to any particular device configurations, unless otherwise claimed. For example, although the IC device 90 as illustrated is a three-dimensional FinFET device, the concepts of the present disclosure may also apply to planar FET devices or GAA devices.

Referring to FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 are elongated fin-like structures that protrude upwardly out of the substrate 110. As such, the active regions 120 may be interchangeably referred to as fin structures 120 hereinafter. Not that in the case of Gate-All-Around (GAA) devices, however, the active region may include the channel formed over (or above) the fin base/mesa, but does not include the fin base/mesa itself. Rather, as will be discussed in more detail below, the active regions of GAA devices comprise nanostructures, such as nano-sheets. In any case, the fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fin structures 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides of each of the fin structures 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction (e.g., having a greater dimension in the X-direction than in other directions), and multiple gate structures 140 are oriented lengthwise along the Y-direction (e.g., having a greater dimension in the Y-direction than in other directions), i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a diagrammatic cross-sectional side view of a portion of an IC device 200 fabricated according to embodiments of the present disclosure, where the IC device 200 is a gate-all-around (GAA) device and may be referred to as a GAA device 200 hereinafter. It is understood that the GAA device 200 may be an NFET in some embodiments, or it may be a PFET in other embodiments.

Referring to FIG. 1C, the cross-sectional view of the GAA device 200 is taken along an X-Z plane, where the X-direction (same X-direction as in FIG. 1A) is the horizontal direction, and the Z-direction (same Z-direction as in FIG. 1A) is the vertical direction. The GAA device 200 includes a substrate 110 and a vertically raised fin structure 120 protruding out of the substrate 110, which may be similar to the fin structure 120 discussed above. In some embodiments, the fin structure 210 includes a semiconductor material, such as silicon. The GAA device 200 includes source/drain features 220, which may be similar to the source/drain features 122 discussed above. Note that source/drain features 220 may refer to a source or a drain, individually or collectively dependent upon the context. The source/drain features 220 are formed over the fin structures 120, and a portion 220′ of each of the source/drain features 220 may protrude downwardly (in the Z-direction) into the fin structure 120. In embodiments where the GAA device 200 is an NFET, the source/drain features 220 include silicon phosphorous (SiP). In embodiments where the GAA device 200 is a PFET, the source/drain features 220 include silicon germanium (SiGe).

The GAA device 200 includes a plurality of channels, for example channels 230 as shown in FIG. 1C. The channels 230 each include a semiconductive material, for example silicon or a silicon compound. The channels 230 are nanostructures (e.g., having sizes that are in a range of a few nanometers) and may also each have an elongated shape and extend in the X-direction. In some embodiments, the channels 230 may each have a nano-wire shape, a nano-sheet shape, a nano-tube shape, etc. The cross-sectional profile of the nano-wire, nano-sheet, or nano-tube may be round/circular, square, rectangular, hexagonal, elliptical, or combinations thereof.

In some embodiments, the lengths (e.g., measured in the X-direction) of the channels 230 may be different from each other. For example, a length of one of the channels 230 may be less than a length of another one of the channels 230. In some embodiments, each of the channels 230 may have a different thickness.

In some embodiments, a spacing (e.g., measured in the Z-direction) between the channels 230 (each channel from adjacent channels) is in a range between about 2 nanometers (nm) and about 12 nm. In some embodiments, a thickness (e.g., measured in the Z-direction) of each of the channels 230 is in a range between about 3 nm and about 15 nm. In some embodiments, a width (e.g., measured in the Y-direction of FIG. 1A) of each of the channels 230 is in a range between about 10 nm and about 150 nm. A plurality of interfacial layers (ILs) may also be formed on the upper and lower surfaces of the channels 230.

The GAA device 200 also includes gate structures that are disposed over and in between the channels 230. The gate structures may include gate dielectric layers 250. In some embodiments, the gate dielectric layers 250 include a high-k gate dielectric. The gate structures further include one or more metal gate electrodes 260. The metal gate electrodes may include work function metal layers. In embodiments where the GAA device 200 is an NFET, the one or more work function metal layers include N-type work function metal layers, such as TiAlC. In embodiments where the GAA device 200 is a PFET, the one or more work function metal layers include P-type work function metal layers, such as TiN.

The metal gate electrodes also include fill metals. In the portion of the gate structure formed over the channels 230, the fill metals are formed over the one or more work function metal layers. In some embodiments, the one or more work function metal layers may have a U-shape and wrap around the fill metal, and the gate dielectric layer 250 may also have a U-shape and wrap around the one or more work function metal layers. In portions of the gate structures formed between the channels 230, the fill metal is circumferentially surrounded (in the cross-sectional view) by the one or more work function metal layers, which is then circumferentially surrounded by the gate dielectric layer 250. It is understood that the gate structures may also include a glue layer that is formed between the one or more work function metal layers and the fill metal to increase adhesion. However, for reasons of simplicity, such a glue layer is not specifically illustrated herein.

The GAA device 200 also includes dielectric materials 265 and inner spacers 270 that are disposed on sidewalls of the gate dielectric layer 250. In some embodiments, the dielectric materials 265 may include gate spacers and/or etching-stop layers. The inner spacers 270 are also disposed between the channels 230 vertically in the Z-direction. The gate spacers and the inner spacers 270 may include a dielectric material, for example a low-k material such as SiOCN, SiON, SiN, or SiOC. Notably, the formation of the inner spacers, including respective manufacturing steps described above, may be optional. That is, the formation of the inner spacers may be omitted, and the inner spacers may not exist in the final structure, in some embodiments.

Additional dielectric layers, such as dielectric layers 275 and 280, may be formed over the gate electrodes 260 and dielectric materials 265. As non-limiting examples, these dielectric layers may include interlayer dielectric (ILD), mask layers, or etching-stop layers. Conductive vias or conducts of the GAA devices 200 may be formed to extend vertically through these dielectric layers 275 and 280, to provide electrical connectivity to the components of the GAA device. For example, the GAA device 200 may include source/drain contacts 285 that are formed over the source/drain features 220. The source/drain contacts 285 may include a conductive material such as cobalt, copper, aluminum, tungsten, or combinations thereof. The source/drain contacts 285 are surrounded by one or more layers, such as barrier layers, which help prevent or reduce diffusion of materials from and into the source/drain contacts 285. In some embodiments, the barrier layer includes TiN, and the barrier layer includes SiN. A silicide layer 290 may also be formed between the source/drain features 220 and the source/drain contacts 285, so as to reduce the source/drain contact resistance. The silicide layer 290 may contain a metal silicide material, such as cobalt silicide in some embodiments. Similarly, a gate contact 295 is formed over one of the gate electrodes 260 to establish electrical connectivity to the gate structure. The gate contact 295 may contain similar conductive materials as the source/drain contacts 285 in some embodiments.

Regardless of whether the transistors of an IC are implemented as a FinFET of FIGS. 1A-1B or a GAA device of FIG. 1C, it is understood that they may benefit from the concepts of the present disclosure, as discussed below in more detail.

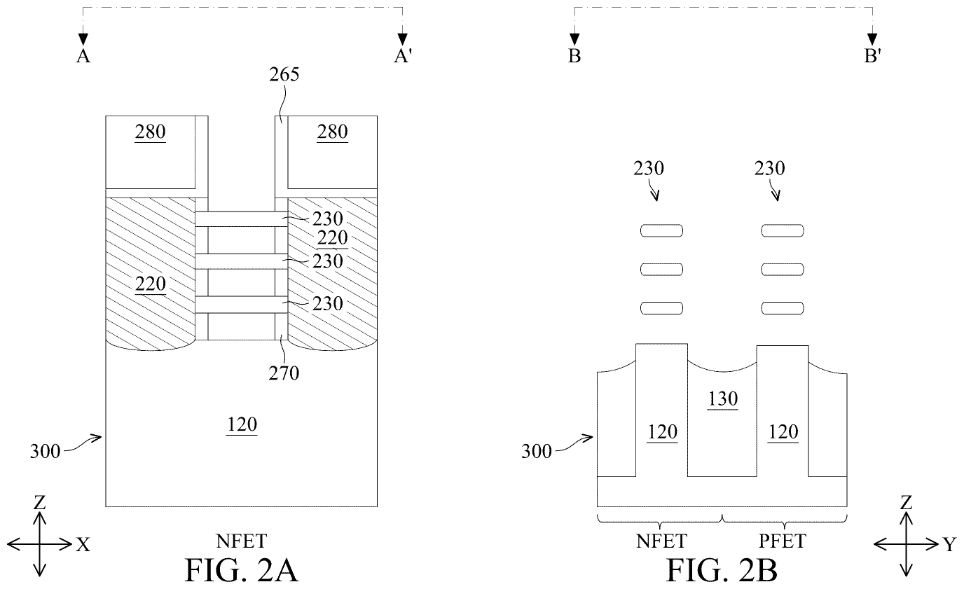

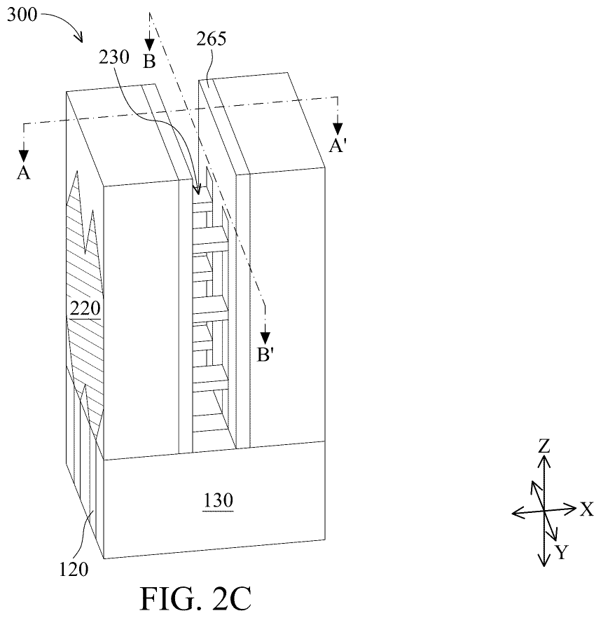

FIGS. 2A, 2B, and 2C are two different diagrammatic fragmentary cross-sectional side views and a diagrammatic fragmentary three-dimensional perspective view, respectively, of an IC device 300 at a particular stage of fabrication according to embodiments of the present disclosure. In more detail, the cross-sectional side view of FIG. 2A is taken along a vertical plane defined by an X-direction horizontally and a Z-direction vertically, and it may hereinafter interchangeably referred to as an X-cut view. The cross-sectional side view of FIG. 2B is taken along a vertical plane defined by a Y-direction horizontally and the Z-direction vertically, and it may hereinafter interchangeably referred to as a Y-cut view. The X-cut is also illustrated in FIG. 2C via a cutline A-A′, and the Y-cut is also illustrated in FIG. 2C via a cutline B-B′. It is understood that the X-direction, the Y-direction, and the Z-direction may be orthogonal or perpendicular to one another.

The IC device 300 is a GAA device in this example. At the stage of fabrication shown in FIGS. 2A-2C, the IC device 300 includes the upwardly protruding fin structure 120 discussed above with reference to FIGS. 1A-1C, which may be formed over a substrate, such as the substrate 110 discussed above. Source/drain features 220 may be formed (e.g., via epitaxial growth) over the fin structure 120. The source/drain features 220 may each include multiple layers with different dopant concentrations. For example, one of the layers of the source/drain features 220 may be a lightly doped layer with a lower dopant concentration, while another one of the layers of the source/drain features 220 may be a heavily doped layer with a higher dopant concentration. The IC device 300 further includes stacks of nano-structure channels 230 formed over semiconductor fin structures 120. The semiconductor fin structures 120 are separated from one another by the isolation structure 130. Note that an uppermost surface of the isolation structure 130 is at a lower vertical elevation (in the Z-direction) than an uppermost surface of the semiconductor fin structure 120. In other words, a side surface of an upper portion of the semiconductor fin structure 120 is exposed. In each stack of the nano-structure channels 230, the nano-structure channels 230 (e.g., containing a semiconductive material such as silicon) are spaced apart from one another in the vertical Z-direction. Each of the nano-structure channels has a channel length (e.g., a horizontal dimension measured in the X-direction) that is greater than a channel thickness (e.g., a vertical dimension measured in the Z-direction). In the illustrated embodiment, the nano-structure channels 230 are implemented as nano-sheets, but it is understood that the nano-structure channels 230 may be implemented as nano-wires, a nano-tubes, or nano-bars in other embodiments, and that the cross-sectional profile of the nano-structure channels 230 may be round/circular, square, rectangular, hexagonal, elliptical, or combinations thereof in various embodiments. At the stage of fabrication of FIGS. 2A-2C, dielectric materials 265, inner spacers 270, and the ILD 280 are also formed for the IC device 300. Note that while FIG. 2A illustrates an NFET device, FIG. 2B illustrates both an NFET device and a PFET device.

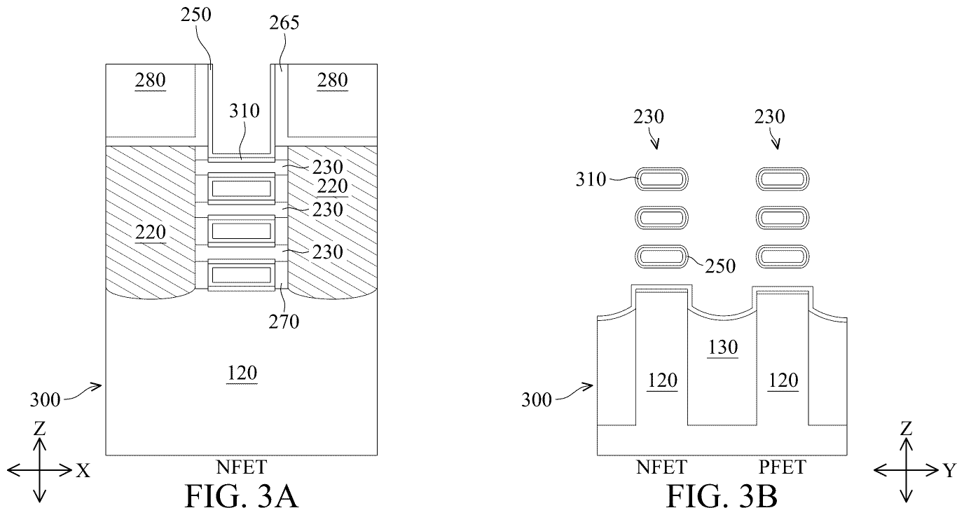

Referring now to FIGS. 3A-3B, the X-cut and Y-cut views of the IC device 300 are illustrated at a stage of fabrication following that of FIGS. 2A-2C. At the stage of fabrication shown in FIGS. 3A-3B, interfacial layers 310 are first formed on the nano-structure channels 230. For example, the interfacial layers 310 may be formed via a suitable deposition process such as CVD, PVD, ALD, or combinations thereof. In the X-cut view of FIG. 3A, the interfacial layers 310 are formed vertically between the nano-structure channels 230. In the Y-cut view of FIG. 3B, each of the interfacial layers 310 is formed to circumferentially surround (e.g., in 360 degrees) a respective one of the nano-structure channels 230. In some embodiments, the interfacial layers 310 may include silicon oxide (SiOₓ), silicon germanium oxide (SiGeOₓ), or combinations thereof.

After the formation of the interfacial layers 310, the gate dielectric layers 250 are formed. For example, the gate dielectric layers 250 may be formed via a suitable deposition process such as CVD, PVD, ALD, or combinations thereof. In some embodiments, the gate dielectric layers 250 may include a high-k dielectric material (e.g., having a dielectric constant greater than about 3.9). For example, the gate dielectric layers 250 may include hafnium oxide (HfO), aluminum oxide (AlOₓ), zirconium oxide (ZrOₓ), lanthanum oxide (La₂O₃), or combinations thereof.

In the X-cut view of FIG. 3A, the gate dielectric layers 250 are formed in between the nano-structure channels 230 (e.g., on the interfacial layers 310 between the nano-structure channels 230). Portions of the gate dielectric layers 250 are also formed on the side surfaces of the inner spacers 270 and on the side surfaces of the dielectric materials 265. In the Y-cut view of FIG. 3B, each of the gate dielectric layers 250 is formed to circumferentially surround (e.g., in 360 degrees) a respective one of the nano-structure channels 230. Specifically, each of the nano-structure channels 230 is circumferentially surrounded by a respective one of the interfacial layers 310, which is then circumferentially surrounded by a respective one of the gate dielectric layers 250.

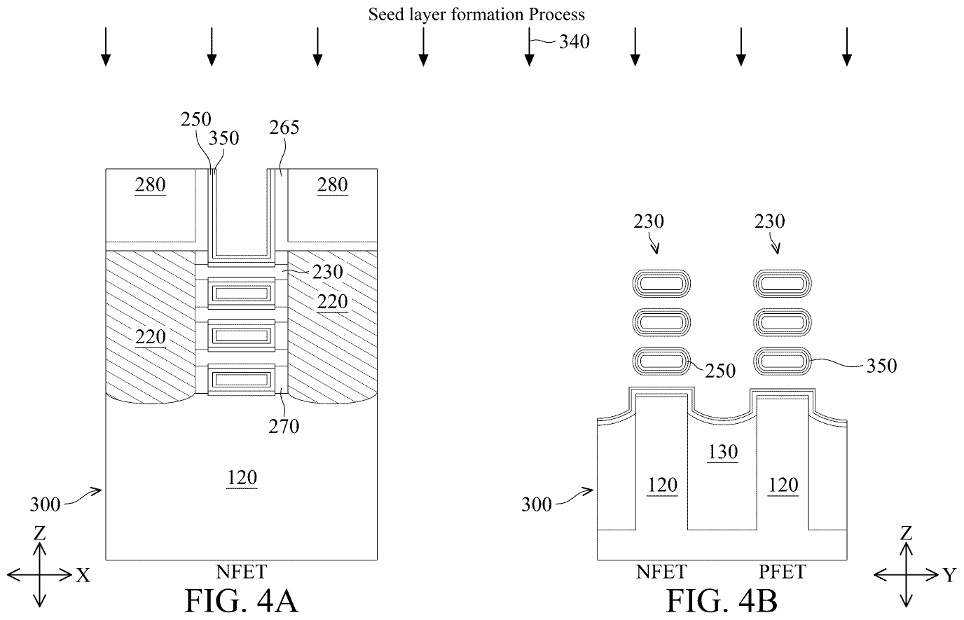

Referring now to FIGS. 4A-4B, the X-cut and Y-cut views of the IC device 300 are illustrated at a stage of fabrication following that of FIGS. 3A-3B. A base layer formation process 340 is performed to the IC device 300 to form base layers 350. For example, the base layer formation process 340 may include a deposition process, such as an ALD process in some embodiments, or another suitable deposition process in some other embodiments. In some embodiments, the base layer formation process 340 deposits a titanium nitride (TiN) material as the base layers 350. In other embodiments, the base layer formation process 340 deposits a tantalum nitride (TaN) material or a titanium silicon nitride (TSN) material as the base layers 350.

Regardless of the type of material deposited as the base layers 350, the result of the base layer formation process 340 is that the base layers are formed on the gate dielectric layers 250. In the X-cut view of FIG. 4A, the base layers 350 are formed in between the nano-structure channels 230 (e.g., on the gate dielectric layers 250 between the nano-structure channels 230). Portions of the base layers 350 are also formed on the side surfaces of the gate dielectric layers 250 above the stack of nano-structure channels 230. In the Y-cut view of FIG. 4B, each of the base layers 350 is formed to circumferentially surround (e.g., in 360 degrees) a respective one of the nano-structure channels 230. Specifically, each of the nano-structure channels 230 is circumferentially surrounded by a respective one of the interfacial layers 310, which is then circumferentially surrounded by a respective one of the gate dielectric layers 250, which is then circumferentially surrounded by a respective one of the base layers 350. In some embodiments, a thickness of each of the base layers 350 is in a range between about 6 angstroms and about 15 angstroms. Such a thickness range is not randomly chosen but specifically configured to facilitate the subsequent formation of a fluorine-containing layer on the base layers 350, as discussed below in more detail.

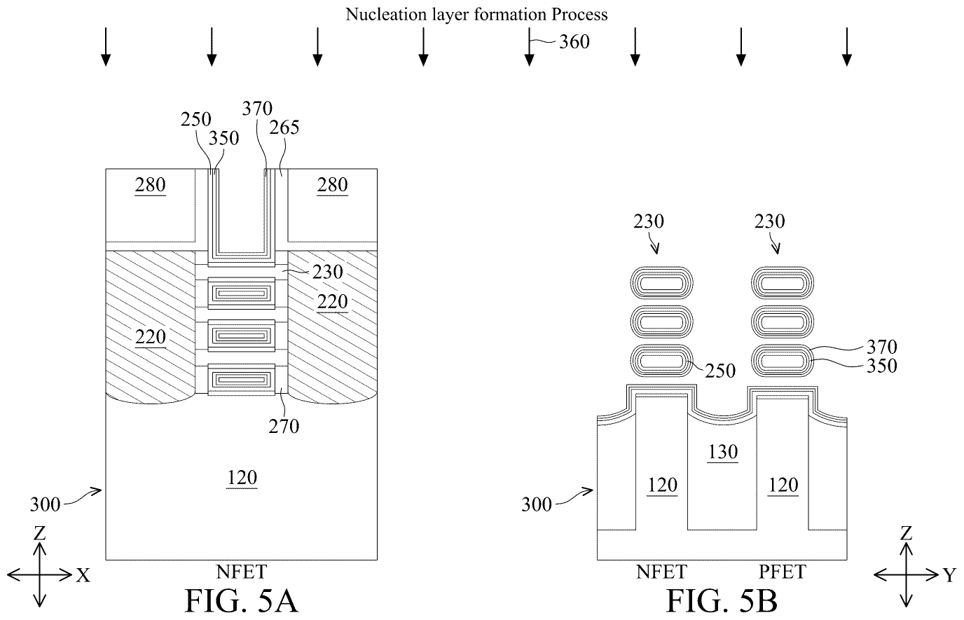

Referring now to FIGS. 5A-5B, the X-cut and Y-cut views of the IC device 300 are illustrated at a stage of fabrication following that of FIGS. 4A-4B. A fluorine-containing layer formation process 360 is performed to the IC device 300 to form fluorine-containing layers 370. For example, the fluorine-containing layer formation process 360 may include a deposition process, such as an ALD process in some embodiments, or another suitable deposition process in some other embodiments. In some embodiments, the fluorine-containing layer formation process 360 deposits a material that contains tungsten and fluorine as the fluorine-containing layers 370. In order to form the tungsten-containing material as the fluorine-containing layers 370, the fluorine-containing layer formation process 360 uses a tungsten-containing and fluorine-containing precursor. For example, in some embodiments, the fluorine-containing layer formation process 360 uses tungsten hexafluoride (WF₆) as the tungsten-containing and fluorine-containing precursor and diborane (B₂H₆) as a reaction gas. Since the reaction gas contains boron, it is understood that a small amount of boron may diffuse into the gate dielectric layer 250. In some embodiments, H₂ or SiH₄ may also be used as a reducing gas.

Regardless of the type of material deposited as the fluorine-containing layers 370, the result of the fluorine-containing layer formation process 360 is that the fluorine-containing layers are formed conformally on the base layers 350. As discussed above, the thickness range of the base layers 350 is specifically configured to be thick enough to allow the deposition of the fluorine-containing layers 370 thereon, while not being too thick to cause problems/damages when the base layers 350 have to be removed in a later process. In the X-cut view of FIG. 5A, the fluorine-containing layers 370 are formed in between the nano-structure channels 230 (e.g., on the base layers 350 between the nano-structure channels 230). Portions of the fluorine-containing layers 370 are also formed on the side surfaces of the base layers 350 above the stack of nano-structure channels 230. In the Y-cut view of FIG. 5B, each of the fluorine-containing layers 370 is formed to circumferentially surround (e.g., in 360 degrees) a respective one of the nano-structure channels 230. Specifically, each of the nano-structure channels 230 is circumferentially surrounded by a respective one of the interfacial layers 310, which is then circumferentially surrounded by a respective one of the gate dielectric layers 250, which is then circumferentially surrounded by a respective one of the base layers 350, which is then circumferentially surrounded by a respective one of the fluorine-containing layers 370. Note that the circumferential disposition of the fluorine-containing layers 370 means that portions of the fluorine-containing layers 370 are disposed in the vertical spaces in between the nano-structure channels 230.

As will be discussed in more detail below, one purpose of the fluorine-containing layers 370 is to incorporate fluorine more uniformly throughout the gate dielectric layers 250. Here, the fact that portions of the fluorine-containing layers 370 are disposed in the vertical spaces in between the nano-structure channels 230 will allow the fluorine to be driven into portions of the gate dielectric layers 250 that are also disposed in the vertical spaces in between the nano-structure channels. In some embodiments, a thickness of each of the fluorine-containing layers 370 is thicker than the thickness of each of the base layers 350. For example, the thickness of the each of the fluorine-containing layers 370 may be in a range between about 20 angstroms and about 24 angstroms. Such a thickness range is not randomly chosen but specifically configured to facilitate the incorporation of fluorine into the gate dielectric layers 250, as discussed below in more detail. In addition, although it may not be immediately apparent based on what is illustrated in FIG. 5B, it is understood that the fluorine-containing layer 370 is thicker at outer surfaces of the stack of the nano-structure channels 230 (e.g., above the topmost surface of the topmost one of the nano-structure channels 230 and/or below the bottommost surface of the bottommost one of the nano-structure channels 230) and thinner at inner surfaces between the nano-structure channels 230 (e.g., between the bottom surface of the topmost one of the nano-structure channels 230 and the top surface of the middle one of the nano-structure channels 230, or between the bottom surface of the middle one of the nano-structure channels 230 and the top surface of the bottommost one of the nano-structure channels 230). As such, after an annealing process (discussed below), the fluorine concentration in the gate dielectric layers 250 at an outer side is higher than at inner side between the nano-structure channels 230. However, during the removal of the base layer 350 and the fluorine-containing layer 370 (also to be discussed below), the outer side suffers more fluorine loss than the inner side. As a result, the fluorine will be distributed more uniformly within the gate dielectric layer 250 around the nano-structure channels 230.

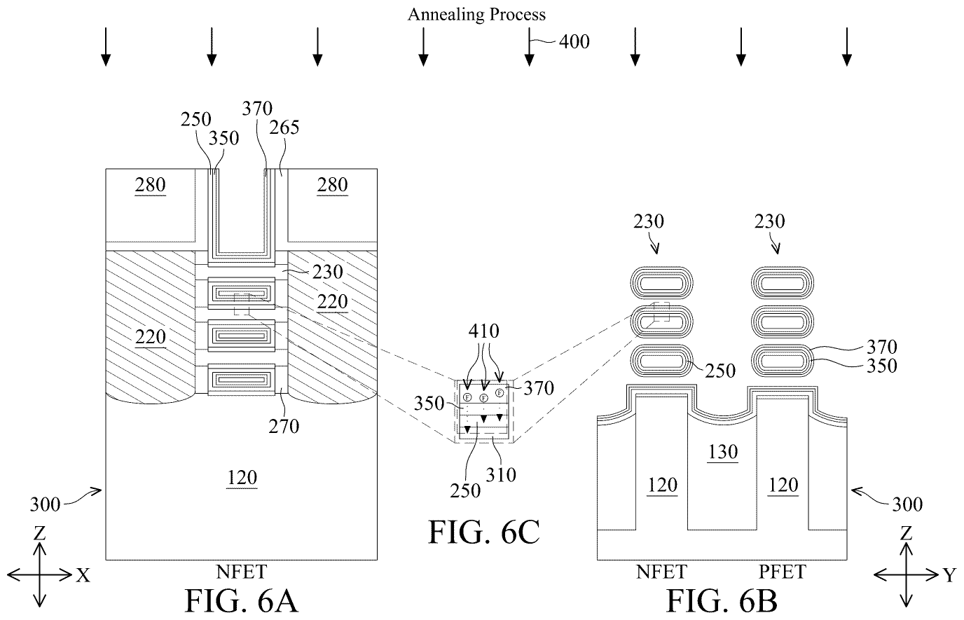

Referring now to FIGS. 6A-6B, the X-cut and Y-cut views of the IC device 300 are illustrated at a stage of fabrication following that of FIGS. 5A-5B. An annealing process 400 is performed to the IC device 300 to drive the fluorine into the gate dielectric layers 250. In some embodiments, the annealing process 400 is performed at an annealing temperature in a range between about 450 degrees Celsius and about 550 degrees Celsius, and for an annealing period in a range between about 10 seconds and about 30 seconds. These process parameters are not randomly chosen but specifically configured to maximize the migration of the fluorine from the fluorine-containing layers 370 into the gate dielectric layers 250, and possibly into the interfacial layers 310, which causes the gate dielectric layers 250 (and possibly the interfacial layers 310) to become doped with fluorine. For example, annealing temperatures that are too low or annealing periods that are too short may not drive a sufficient amount of fluorine into the gate dielectric layer 250. On the other hand, annealing temperatures that are too high or annealing periods that are too long may cause the gate dielectric layer 250 to become overdosed with fluorine or otherwise degrade device performance. Here, by specifically configuring the annealing process parameters to be within the above ranges, a sufficient amount of fluorine will be driven into the gate dielectric layer 250 without overdosing the gate dielectric layer 250 or degrading the device performance.

The migration of the fluorine is illustrated in more detail in FIG. 6C, which illustrates a magnified cross-sectional view of a portion of either the IC device 300 in FIG. 6A or FIG. 6B. Specifically, the magnified view of FIG. 6C includes the interfacial layer 310, the gate dielectric layer 250 disposed on the interfacial layer 310, the base layer 350 disposed on the gate dielectric layer 250, and the fluorine-containing layer 370 disposed on the base layer 350. As discussed above, the formation of the fluorine-containing layer 370 includes using WF₆ as a precursor, which means that the fluorine-containing layer 370 also contains fluorine. The fluorine within the fluorine-containing layer 370 is illustrated in FIG. 6C as fluorine atoms 410. The annealing process 400 provides an energy boost for these fluorine atoms 410 and causes them to move into the gate dielectric layers 250. In some embodiments, the energy boost provided by the annealing process 400 is sufficient to cause the fluorine atoms to move into the interfacial layer 310 as well, although at a lower concentration level or dosage than in the gate dielectric layer 250.

Note that while the magnified view of FIG. 6C merely illustrates a portion of the layers 310, 250, 350, and 370 disposed in the vertical spaces between the nano-structure channels 230, it is understood that the same fluorine migration is occurring elsewhere as well, for example, on portions of these layers disposed on side surfaces of each of the nano-structure channels 230. In this manner, the fluorine doping occurs more uniformly. That is, the gate dielectric layer 250 (and the interfacial layer 310 as well) may be conformally doped throughout, regardless of whether the location is on the side portions, or directly in between the nano-structure channels 230 vertically. As discussed above, fluorine can increase an energy barrier needed for MBE to occur. For example, fluorine passivates dangling bonds and/or reduces oxygen vacancies in the gate dielectric layers 250 and interfacial layers 310. Therefore, the incorporation of fluorine throughout the gate dielectric layers 250 (and in the interfacial layers 310) herein can alleviate the problems caused by MBE and improve device quality and/or performance. Also note that, as discussed above, the fluorine-containing layer 370 was formed in a manner such that it is thicker at outer surfaces of the stack of the nano-structure channels 230 and thinner at inner surfaces between the nano-structure channels 230. Therefore, after an annealing process 400 has been performed, the fluorine concentration in the gate dielectric layers 250 at an outer side is higher than at inner side between the nano-structure channels 230.

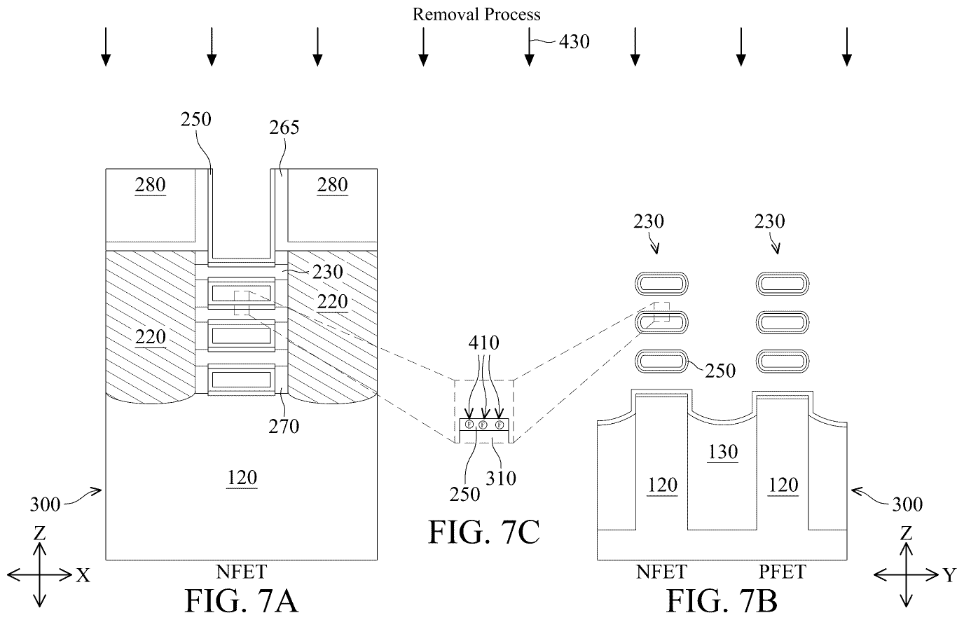

Referring now to FIGS. 7A-7B, the X-cut and Y-cut views of the IC device 300 are illustrated at a stage of fabrication following that of FIGS. 6A-6B. At this stage of fabrication, the fluorine atoms 410 have already been driven into the gate dielectric layers 250, as shown in the magnified view of FIG. 7C. Some of the fluorine atoms 410 may also have been driven into the interfacial layers 310, though this is not specifically illustrated in FIG. 7C for reasons of simplicity. A removal process 430 is then performed to the IC device 300 to remove the fluorine-containing layers 370 and the base layers 350. In some embodiments, the removal process 430 includes one or more etching processes, such as a wet etching process. In some embodiments, NH₄OH and H₂O₂ may be used as etchants for at least one of the etching processes as a part of the removal process 430. Note that, as discussed above, the fluorine concentration in the gate dielectric layers 250 at an outer side is higher than at inner side between the nano-structure channels 230 initially (e.g., after the annealing process 400 has been performed but before the removal process 430 has been performed). However, during the removal of the base layer 350 and the fluorine-containing layer 370 (as a part of the removal process 430), the outer side of the gate dielectric layer 250 may experience more fluorine loss than the inner side. As a result, the fluorine will be distributed more uniformly within the gate dielectric layer 250 around the nano-structure channels 230 after the removal process 430 has been performed.

Also note that different etchants and/or different etching process parameters may be used depending on the material compositions of the base layers 350 and the fluorine-containing layers 370. For example, the removal process 430 may be performed with a temperature in a range between about 50 degrees Celsius and 80 degrees Celsius, and with a concentration of H₂O₂ in a range between about 17% and about 40%. In embodiments where TiN is used to implement the base layers 350, a lower temperature and/or a lower concentration of H₂O₂ may be used to perform the removal process 430, since TiN is more easily removable. However, in other embodiments where TaN or TSN are used to implement the base layers 350, a higher temperature and/or a higher concentration of H₂O₂ may be used to perform the removal process 430, since TaN and TSN are not as easily removable as TiN. In some embodiments, a dry etching process may be used to perform at least a part of the removal process 430, so as to achieve better efficacy for removing the TaN or TSN as the base layers 350. Regardless of the type of materials used to implement the base layers 350 and/or the specific process details of the removal process 430, it is understood that a small amount of residue from the base layer 350 may still remain on the surfaces of the gate dielectric layers 250, such as residue that contains Ti, Ta, or Si. The presence of such residue may also be a unique physical characteristic of the IC device 300 fabricated according to various aspects of the present disclosure, as discussed in more detail below.

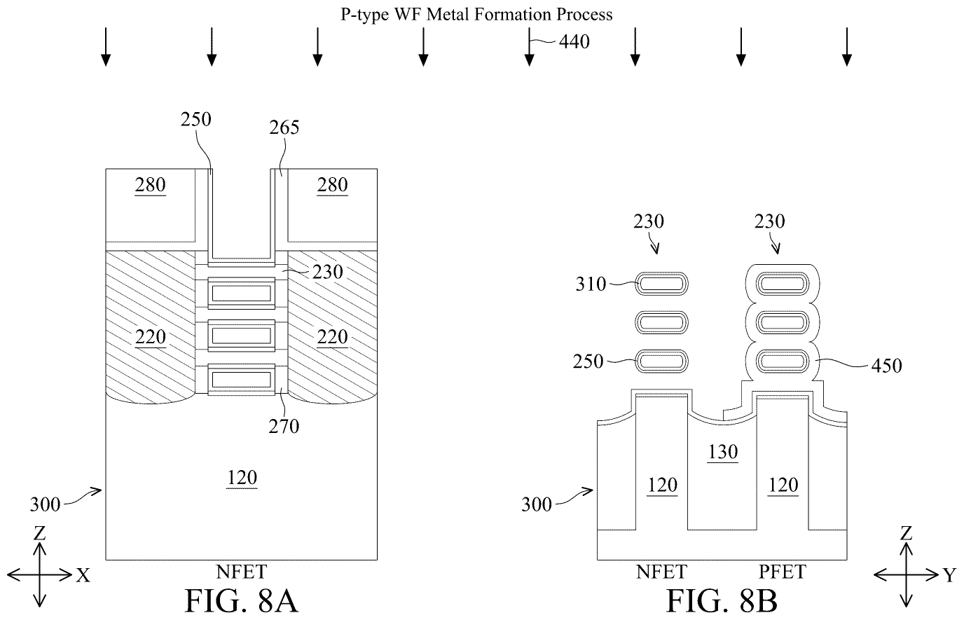

Referring now to FIGS. 8A-8B, the X-cut and Y-cut views of the IC device 300 are illustrated at a stage of fabrication following that of FIGS. 7A-7B. A P-type WF metal formation process 440 is performed to the IC device 300 to form the P-type WF metal layer 450. For example, the P-type WF metal formation process 440 may include a deposition process, such as CVD, PVD, ALD, or combinations thereof. In some embodiments, TiAlC, Al, TiAl, TaN, TaAlC, TiN, TiC, Co, or combinations thereof may be implemented as the P-type WF metal layer 450. As shown in FIG. 8B, the P-type WF metal layer 450 circumferentially surrounds the nano-structure channels 230 of the PFET device, as well as the interfacial layers 310 and the gate dielectric layers 250 formed thereon. Portions of the P-type WF metal layer 450 are also formed over the fin structure 120 and portions of the isolation structures 130 of the PFET device. However, the NFET device has no P-type WF metal layer 450 formed thereon. In some embodiments, a masking layer is formed in the NFET device before the P-type WF metal layer 450 is deposited, which prevents the P-type WF metal layer 450 from being formed in the NFET device. The masking layer may then be removed after the deposition of the P-type WF metal layer 450. In some embodiments, the P-type WF metal layer 450 is deposited on both the NFET device and the PFET device, and the P-type WF metal layer 450 is removed on the NFET device side, and an N-type WF metal layer is deposited on both the NFET device and the PFET device. Note that since FIG. 8A illustrates the NFET device but not the PFET device, no portion of the P-type WF metal layer 450 is shown in FIG. 8A. In any case, it is understood that the P-type WF metal layer 450 may serve as the WF metal component of a metal-containing gate electrode of the PFET device.

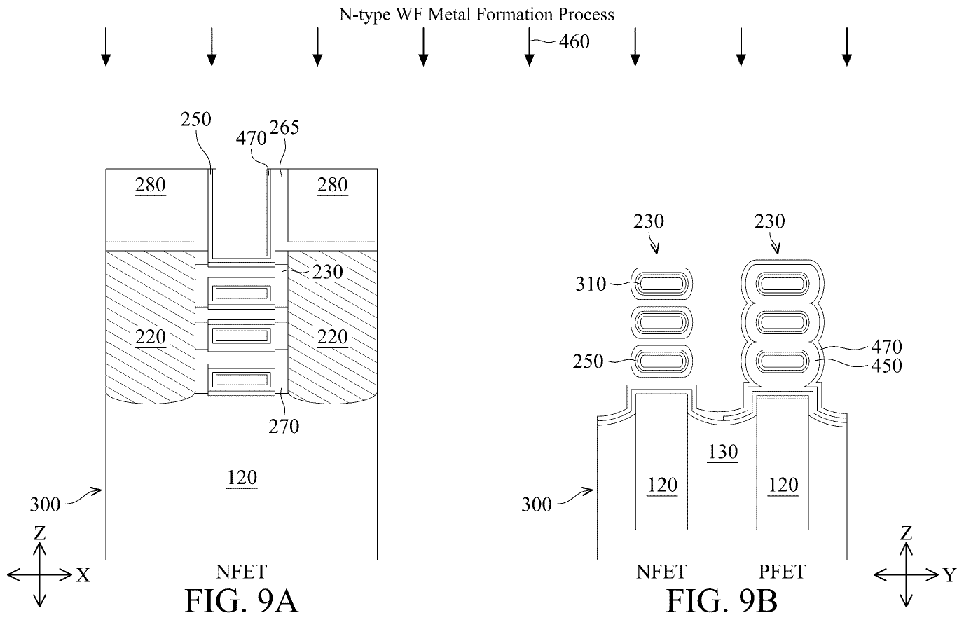

Referring now to FIGS. 9A-9B, the X-cut and Y-cut views of the IC device 300 are illustrated at a stage of fabrication following that of FIGS. 8A-8B. An N-type WF metal formation process 460 is performed to the IC device 300 to form the N-type WF metal layer 470. For example, the N-type WF metal formation process 460 may include a deposition process, such as CVD, PVD, ALD, or combinations thereof. In some embodiments, TaN, TaAlC, TiN, TiC, Co, TiAl, HfTi, TiSi, TaSi, or combinations thereof may be implemented as the N-type WF metal layer 470. In the X-cut view of FIG. 9A, portions of the N-type WF metal layer 470 are formed on the gate dielectric layers 250 of the NFET device. In the Y-cut view of FIG. 9B, the N-type WF metal layer 470 circumferentially surrounds the nano-structure channels 230 of the NFET device, as well as the interfacial layers 310 and the gate dielectric layers 250 formed thereon. Portions of the N-type WF metal layer 470 are also formed over the fin structure 120 of the NFET device and portions of the isolation structures 130. Portions of the N-type WF metal layer 470 are further formed on the P-type WF metal layer 450 of the PFET device. In any case, it is understood that the N-type WF metal layer 470 may serve as the WF metal component of a metal-containing gate electrode of the NFET device. Note that the inner spacers 270 provide insulation between the WF metal layer 470 and the source/drain features 220.

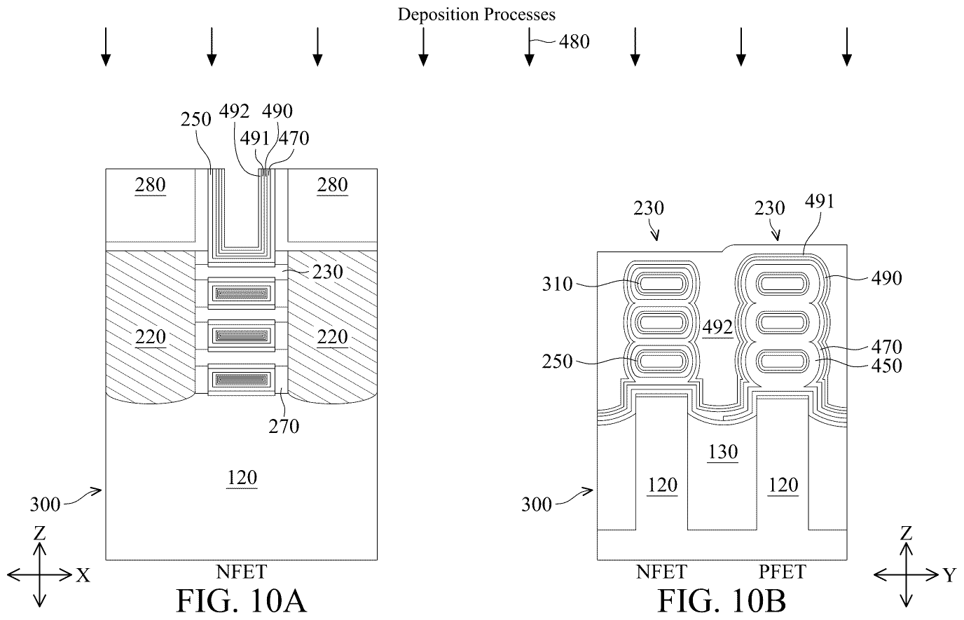

Referring now to FIGS. 10A-10B, the X-cut and Y-cut views of the IC device 300 are illustrated at a stage of fabrication following that of FIGS. 9A-9B. A plurality of deposition processes 480 may be performed to the IC device 300 to form a shield layer 490, a capping layer 491, and a glue layer 492. The deposition processes 480 may include CVD, PVD, ALD, or combinations thereof. The shield layer 490 is deposited on the N-type WF metal layer 470, the capping layer 491 is deposited on the shield layer 490, and the glue layer 492 is deposited on the capping layer 491. In some embodiments, iTiN, WN, or TaN may be implemented as the shield layer 490, Si or SiTi may be implemented as the capping layer 491, and Ti, TiN, or TSN may be implemented as the glue layer 492. In some embodiments, the glue layer 492 may have a thickness in a range between about 40 angstroms and about 100 angstroms. Such a thickness range helps the glue layer 492 to facilitate the formation of a gate electrode material in a subsequent process.

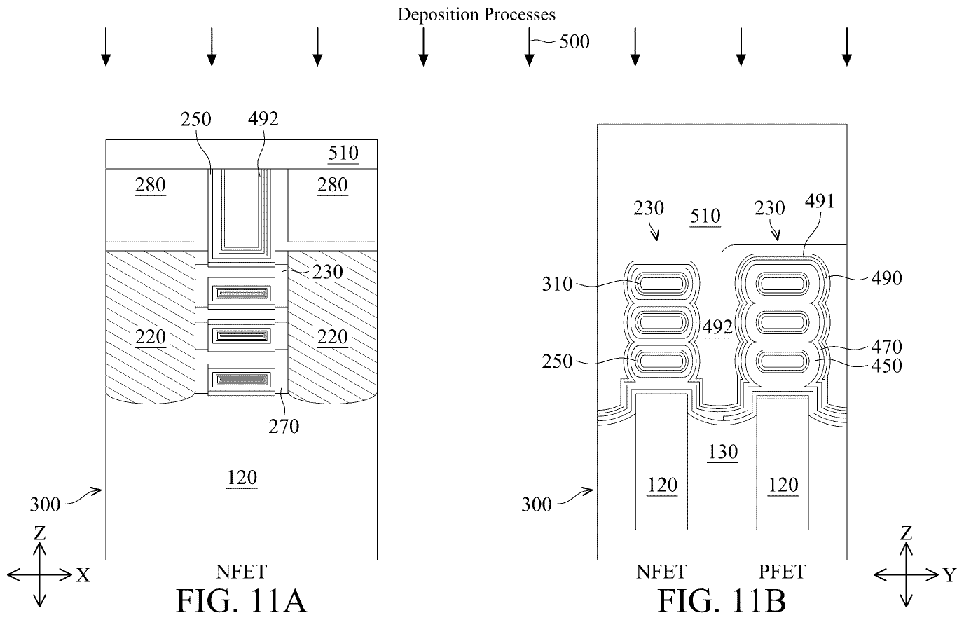

Referring now to FIGS. 11A-11B, the X-cut and Y-cut views of the IC device 300 are illustrated at a stage of fabrication following that of FIGS. 10A-10B. One or more deposition processes 500, such as a CVD process, may be performed to the IC device 300 to form a fill metal component 510 of the gate electrodes of the PFET device and the NFET device. In that regard, the P-type WF metal layer 450 may serve as the WF metal portion of the gate electrode of the PFET device, and the N-type WF metal layer 470 may serve as the WF metal portion of the gate electrode of the NFET device. Meanwhile, the fill metal component 510 may serve as a main conductive component of the gate electrode of both the PFET device and the NFET device. As shown in FIGS. 11A-11B, the fill metal component 510 is formed on the glue layer 492. Furthermore, as shown in FIG. 11A, the fill metal component 510 not only fills the upwardly-facing recess defined by the glue layer 492, but portions of the fill metal component 510 are also formed over the ILD 280. In some embodiments, the fill metal component 510 may include tungsten. In other embodiments, the fill metal component 510 may include tungsten, copper, aluminum, cobalt, ruthenium, or another suitable conductive material. As discussed above, the glue layer 492 facilitates the formation of the fill metal component 510, since it would have been difficult for the fill metal component 510 to be formed directly on the capping layer 491, the shield layer 490, or the gate dielectric layer 250. It is understood, however, that in some embodiments (e.g., small Lg device), the trench may be filled with the glue layers without tungsten or the other types of conductive material discussed above.

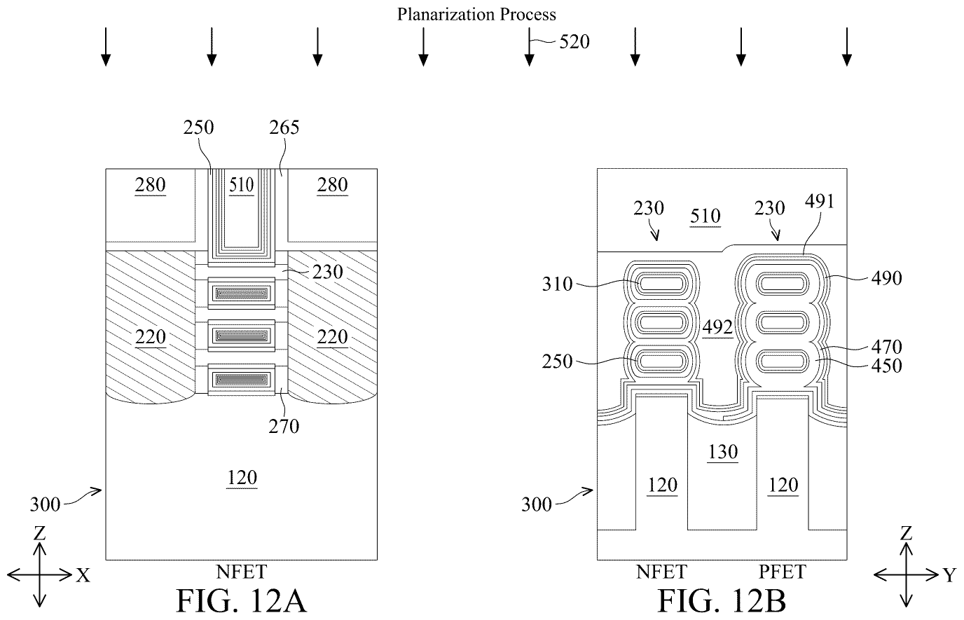

Referring now to FIGS. 12A-12B, the X-cut and Y-cut views of the IC device 300 are illustrated at a stage of fabrication following that of FIGS. 11A-11B. A planarization process 520 may be performed to the IC device 300. In some embodiments, the planarization process 520 includes a chemical mechanical polishing (CMP) process, which uses chemical etching and mechanical grinding to remove portions of the fill metal component 510 until the upper surfaces of the fill metal component 510 is substantially coplanar with the upper surfaces of the ILD 280, the gate dielectric layer 250, and the dielectric materials 265. Note that the tungsten-filled-in trench may be optional and may not be implemented in certain embodiments.

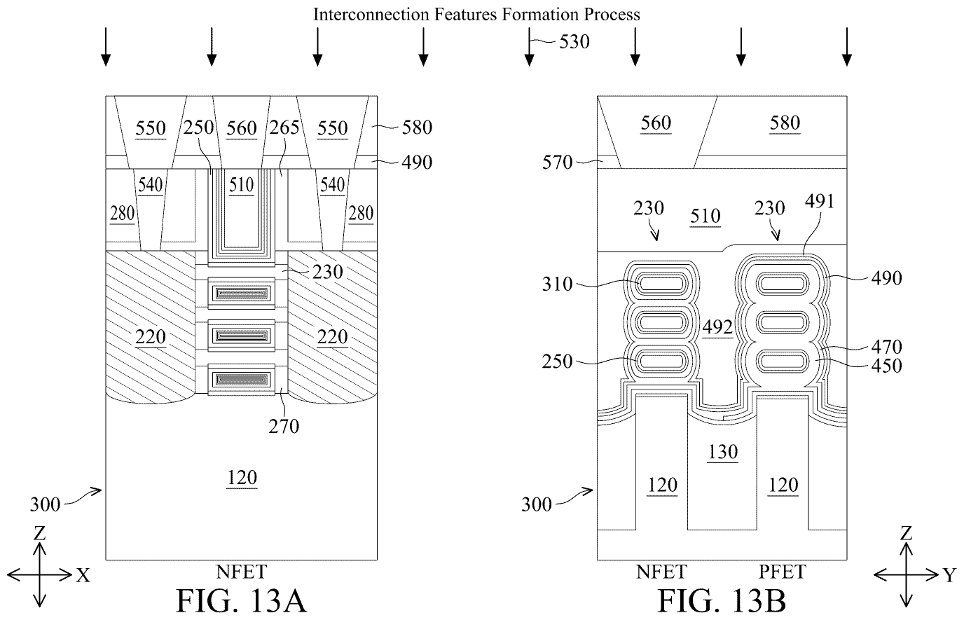

Referring now to FIGS. 13A-13B, the X-cut and Y-cut views of the IC device 300 are illustrated at a stage of fabrication following that of FIGS. 12A-12B. An interconnection features formation process 530 may be performed to the IC device 300. The interconnection features formation process 530 may form various interconnection features, including source/drain contacts 540 formed over the source/drain features 220, source/drain vias 550 formed over the source/drain contacts 540, and gate contacts 560 formed over the gate electrode (e.g., formed over the fill metal component 510 of the gate electrode). In some embodiments, the interconnection features formation process 530 may include one or more etching processes to etch source/drain contact openings through the ILD 280, as well deposition processes (e.g., CVD, PVD, ALD, etc.) to fill these etched source/drain contact openings with a conductive material as the source/drain contacts 540. Thereafter, the interconnection features formation process 530 may include one or more deposition processes (e.g., CVD, PVD, ALD, etc.) to form an etching-stop layer 570 over the upper surfaces of the ILD 280, the source/drain contacts 540, and the gate electrode, as well as an ILD 580 over the etching-stop layer 570, which may have a different material composition than the etching-stop layer 570. Thereafter, the interconnection features formation process 530 may include one or more etching processes to etch source/drain via openings and gate contact openings through the ILD 580 and the etching-stop layer 570, as well deposition processes (e.g., CVD, PVD, ALD, etc.) to fill these etched source/drain via openings and gate contact openings with a conductive material as the source/drain vias 550 and the gate contact 560. Note that each of the source/drain contacts 540, source/drain vias 550, and/or the gate contact 560 may have a cross-sectional side view profile (in both the X-cut view of FIG. 13A and the Y-cut view of FIG. 13B) that is wider at the top and narrower at the bottom. It is also understood that the ILD 580 and/or the other dielectric materials used to insulate the source/drain contacts 540, source/drain vias 550, and/or the gate contact 560 may have a dielectric constant value that is smaller than the dielectric constant value of the gate dielectric layers 250.

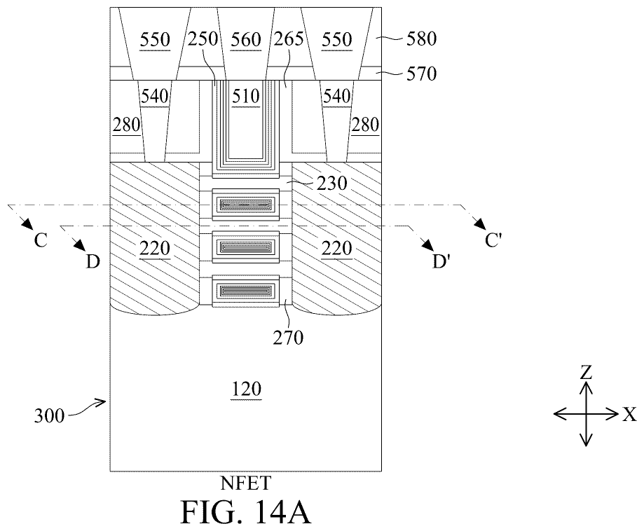

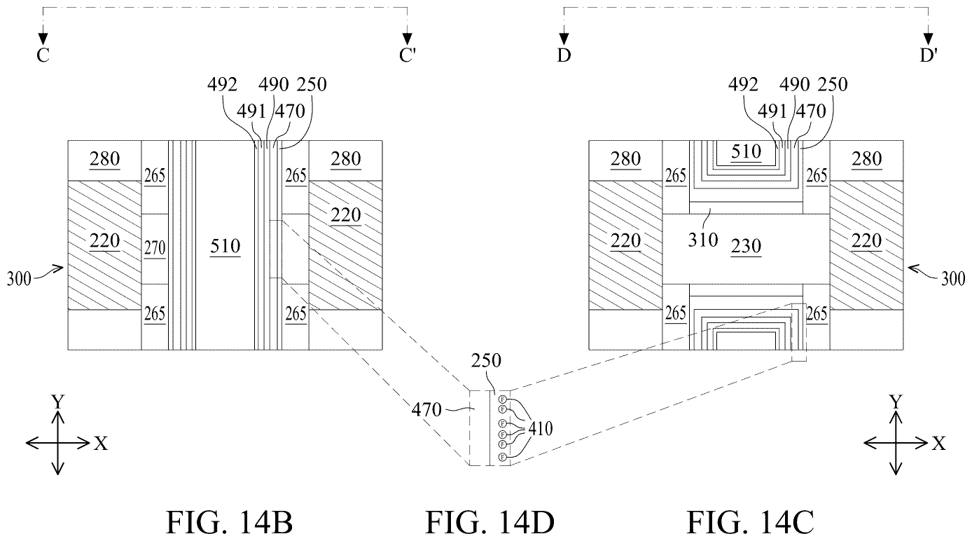

Referring now to FIGS. 14A, 14B, 14C, and 14D, various aspects of the IC device 300 are illustrated in more detail via cross-sectional side and top views. For example, FIG. 14A illustrates the X-cut cross-sectional side view of the IC device 300 at the same stage of fabrication as illustrated in FIG. 13A. Meanwhile, both FIGS. 14B and 14C correspond to a horizontal plane defined by the X-direction and the Y-direction, but they are taken at different regions of the IC device. In particular, FIG. 14B is a planar top view of the IC device 300 taken along a cutline C-C′ (e.g., cutting within the metal gate) illustrated in FIG. 14A, and FIG. 14C is a planar top view of the IC device 300 taken along a cutline D-D′ (e.g., cutting within one of the nano-structure channels 230) illustrated in FIG. 14A. FIG. 14D is a magnified top view showing a portion of the IC device of FIG. 14B or FIG. 14C, which illustrates the dopant fluorine disposition within the IC device 300 at this stage of fabrication.

As shown in the top view of FIG. 14B, the fill metal component 510 of the gate electrode extends in the Y-direction (e.g., having a longer dimension in the Y-direction than in the X-direction). The glue layer 492 is disposed on sidewalls of the fill metal component 510 of the gate electrode, the capping layer 491 is disposed on sidewalls of the glue layer 492, the shield layer 490 is disposed on sidewalls of the capping layer 491, the N-type WF metal layer 470 is disposed on sidewalls of the shield layer 490, and the gate dielectric layer 250 is disposed on sidewalls of the N-type WF metal layer 470. Dielectric materials 265 are disposed on a portion of the sidewalls of the gate dielectric layer 250, while inner spacers 270 are disposed on a different portion of the sidewalls of the gate dielectric layer 250. Note that the inner spacers 270 provide physical and electrical insulation between the source/drain features 220 and the gate structure that includes the gate dielectric layer 250 and the N-type WF metal layer 470. The source/drain features 220 and the ILD 280 are disposed on sidewalls of the dielectric materials 265 and inner spacers 270. Note that the inner spacers may be optional in some other embodiments.

As shown in the top view of FIG. 14C, the nano-structure channel 230 (e.g., a silicon channel) extends in the X-direction (e.g., having a longer dimension in the X-direction than in the Y-direction). Source/drain features 220 are disposed on sidewalls of the nano-structure channel 230 that extend in the Y-direction. Meanwhile, the interfacial layer 310 and dielectric materials 265 are disposed on sidewalls of the nano-structure channel 230 that extend in the X-direction. The gate dielectric layer 250 is disposed on the sidewall of the interfacial layer 310, and the gate dielectric layer 250, the N-type WF metal layer 470, the shield layer 490, the capping layer 491, and the glue layer 492 collectively define a recess in which the fill metal component 510 of the gate electrode is located.

At this stage of fabrication, the fluorine atoms 410 are dispersed throughout the gate dielectric layer 250, as shown in the magnified top view of FIG. 14D. However, since the N-type WF metal layer 470 is formed after the fluorine atoms 410 have been driven into the gate dielectric layer 250 and after the removal of the fluorine-containing layer 370 and the base layer 350, the result is that the N-type WF metal layer 470 has substantially fewer fluorine atoms 410 than the gate dielectric layer 250. For example, as shown in the top view of FIG. 14B, the gate dielectric layer 250 and the N-type WF metal layer 470 may define an interface. The fluorine atoms 410 are disposed on a first side of the interface corresponding to the gate dielectric layer 250, but not on a second side of the interface corresponding to the N-type WF metal layer 470. The same is true for the P-type WF metal layer 450 (see FIG. 8B), but since FIGS. 14A-14D illustrate the NFET device, the P-type WF metal layer 450 (and the absence of the fluorine atoms 410 therein) is not directly visible in FIGS. 14A-14D.

The significantly greater presence of fluorine atoms 410 within the gate dielectric layer 250 than the N-type WF metal layer 470 or the P-type WF metal layer 450 is one of the unique physical characteristics of the present disclosure, and it is also an inherent result of the unique fabrication process flow discussed above being performed (e.g., forming base layer and fluorine-containing layer on the gate dielectric layer, performing annealing process to drive fluorine into the gate dielectric layer, removing the base layer and fluorine-containing layer, and then forming the WF metal layers thereafter). It is understood, however, that the presence of the fluorine atoms 410 within the gate dielectric layer 250 (or in the WF metal layer 470) may not be easily detectable using techniques such as Transmission Electron Microscopy (TEM) alone. In some embodiments, a combination of TEM and an Energy Dispersive X-ray Spectroscopy (EDS) may be utilized to detect the presence of the fluorine atoms 410 within the gate dielectric layer 250 (or in the WF metal layer 470). For example, TEM may provide a high-resolution image of the gate dielectric layer 250, while EDS offers an elemental analysis of the contents of the gate dielectric layer 250, which would identify the types and amounts of the various elements (including fluorine) that is present at a specific location within the gate dielectric layer 250. In some cases, an energy analysis via EDS may be used to detect and/or measure the presence of the fluorine atoms 410 within the gate dielectric layer 250 (or in the interfacial layer 310 or in the WF metal layer 470).

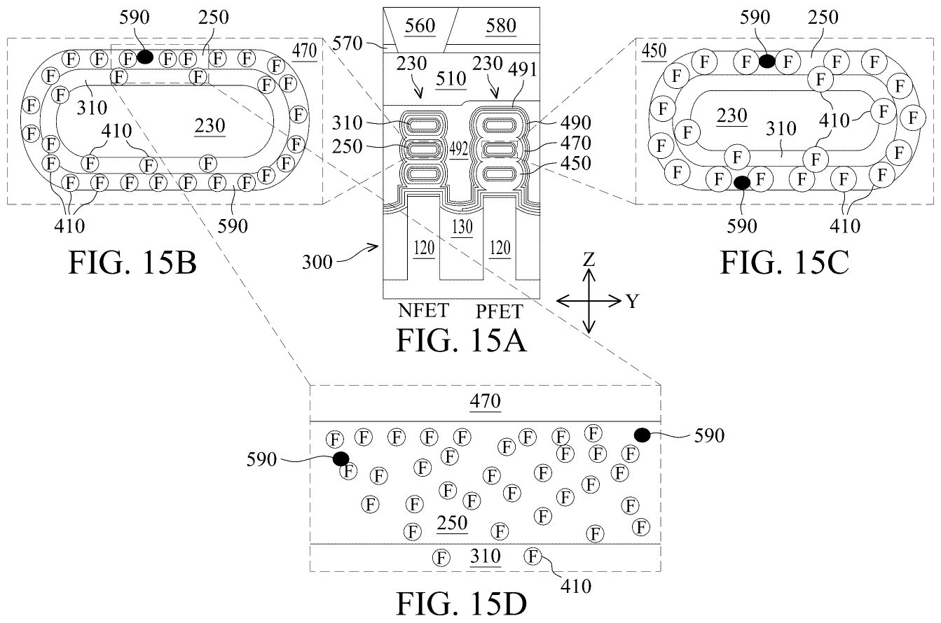

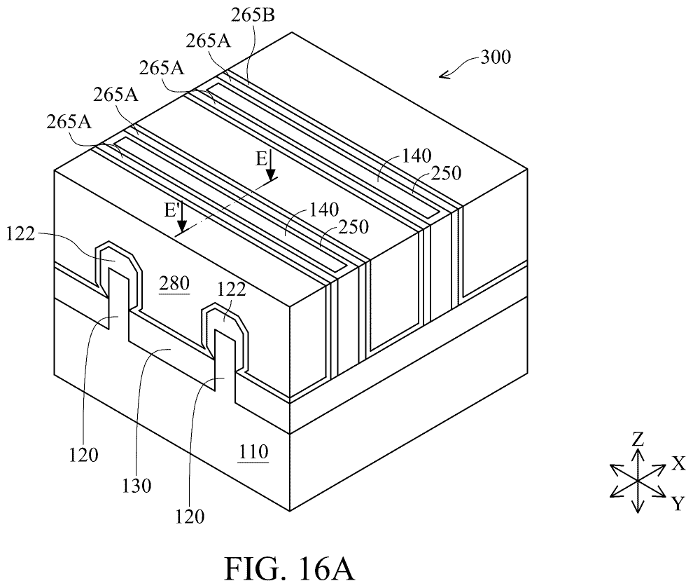

Referring now to FIGS. 15A, 15B, 15C, and 15D, various aspects of the IC device 300 are illustrated in more detail. For example, FIG. 15A illustrates the Y-cut cross-sectional side view of the IC device 300 at the same stage of fabrication as illustrated in FIG. 13B. FIG. 15B is a magnified Y-cut cross-sectional side view of an NFET portion of the IC device 300 that includes one of the nano-structure channels 230, the interfacial layer 310 that circumferentially surrounds the nano-structure channel 230, the gate dielectric layer 250 that circumferentially surrounds the interfacial layer 310, and the N-type WF metal layer 470 that circumferentially surrounds the gate dielectric layer 250. FIG. 15C is a magnified Y-cut cross-sectional side view of an PFET portion of the IC device 300 that includes one of the nano-structure channels 230, the interfacial layer 310 that circumferentially surrounds the nano-structure channel 230, the gate dielectric layer 250 that circumferentially surrounds the interfacial layer 310, and the P-type WF metal layer 450 that circumferentially surrounds the gate dielectric layer 250. FIG. 15D is a further magnified Y-cut cross-sectional side view of a region of the NFET portion of the IC device 300 illustrated in FIG. 15B, which includes a portion of the interfacial layer 310, a portion of the gate dielectric layer 250, and a portion of the N-type WF metal layer 470.

As shown in FIGS. 15B and 15C, the fluorine atoms 410 have been driven into the gate dielectric layer 250 at this stage of fabrication. The fluorine atoms 410 are not just disposed on the side portions of the gate dielectric layer 250, but throughout different regions of the gate dielectric layer 250, including on the horizontally extending segments (e.g., extending in the Y-direction) that are disposed directly between the adjacent ones of the nano-structure channels 230 of the channel stack. In some embodiments, a first segment of the gate dielectric layer 250 disposed directly above or below one of the nano-structure channels 230 in the cross-sectional side view has a first average concentration level of fluorine, and a second segment of the gate dielectric layer 250 disposed beside the nano-structure channel 230 laterally in the cross-sectional side view has a second average concentration level of fluorine, where a ratio of the first concentration level of fluorine and the second concentration level of fluorine is in a range between about 0.8:1 and about 1.2:1. In other words, there is not much of a difference in terms of fluorine content between horizontally-extending segment of the gate dielectric layer 250 disposed directly above or below the nano-structure channel 230 and a vertically-extending segment of the gate dielectric layer 250 disposed on side surfaces of the nano-structure channel 230.

However, the concentration level of fluorine inside the gate dielectric layer 250 may vary as a function of depth. Specifically, as the depth increases (e.g., closer to the interfacial layer 310 and farther away from the WF metal layers 450/470) within the gate dielectric layer 250, the concentration level of the fluorine atoms 410 may decrease. For example, at or near an outer surface of the gate dielectric layer 250 (e.g., near the interface formed between the gate dielectric layer 250 and either the N-type WF metal layer 470 (in the case of the NFET) or the P-type WF metal layer 450 (in the case of the PFET), there may be a first concentration level of fluorine atoms 410. In comparison, at or near an inner surface of the gate dielectric layer 250 (e.g., near the interface formed between the gate dielectric layer 250 and the interfacial layer 310), there may be a second concentration level of fluorine atoms 410 that is less than the first concentration level.

Furthermore, the fluorine atoms 410 may be driven at least partially into the interfacial layer 310 as well. However, since the location of the interfacial layer 310 is farther away from the base layer 350 and the fluorine-containing layer discussed above (see e.g., FIGS. 6A-6B), not as much of the fluorine atoms 410 are driven into the interfacial layer 310 compared to the gate dielectric layer 250. For example, an atomic percentage of the fluorine atoms 410 in the gate dielectric layer 250 is greater than an atomic percentage of the fluorine atoms 410 in the interfacial layer 310. Alternatively stated, an average fluorine concentration level of fluorine inside the interfacial layer 310 is less than an average fluorine concentration level of fluorine inside the gate dielectric layer 250.

In any case, the fluorine concentration level inside the gate dielectric layer 250 and/or the interfacial layer 310 may be in a range between about 15% and about 20% in terms of atomic percentage, which may be measured via an X-ray photoelectron spectroscopy (XPS) analysis. Such a fluorine concentration level range is not randomly chosen by specifically configured to optimize device performance. On the one hand, the fluorine concentration level is configured to be sufficiently high to effectively reduce the adverse effects caused by the MBE discussed above. For example, the presence of the fluorine atoms 410 in different regions of the gate dielectric layer 250 and the interfacial layer 310 herein can increase barrier energy required for the metal diffusion (e.g., Al diffusion across the NFET/PFET boundary) to occur. In some embodiments, the barrier energy may be increased from between about 1~1.4 electronic volts to between about 4.2~4.6 electronic volts. Due to the higher barrier energy, less metal diffusion will occur, which then alleviates the MBE. On the other hand, the fluorine concentration level is configured to not be too high, so as to avoid unintended effects with respect to N-dipole tuning, since fluorine may react with lanthanum. In this manner, the fluorine concentration level herein is optimally tuned to achieve MBE reduction without interfering with N-dipole tuning.

Another unique physical characteristic of the IC device 300 is the potential presence of intermix compounds 590 within the gate dielectric layer 250. As discussed above, the base layer 350 (see FIGS. 4A-4B) was removed at an earlier fabrication stage (e.g., by the removal process 430 discussed above with reference to FIGS. 7A-7C). However, some amounts of the residue of the base layer 350 may still remain even after the performance of the removal process 430. The residue may form the intermix compounds 590 within the gate dielectric layer 250. Depending on the candidate material used to implement the base layer 350, the material composition of the intermix compounds 590 may change as well. For example, in embodiments where TiN was used to implement the base layer 350, the intermix compounds 590 may include a Ti-containing material. In embodiments where TSN was used to implement the base layer 350, the intermix compounds 590 may include a Si-containing material. In embodiments where TaN was used to implement the base layer 350, the intermix compounds 590 may include a Ta-containing material. Regardless of the material composition of the intermix compounds 590, it is understood that the concentration of the intermix compounds 590 within the gate dielectric layer 250 is significantly lower than the concentration of fluorine atoms 410. In some embodiments, the concentration level of fluorine atoms 410 within the gate dielectric layer 250 is at least 10 times higher than the concentration level of the intermix compounds within the gate dielectric layer 250. It is understood that the detection and/or measurement of the intermix compounds 590 may be done using the same techniques discussed above for measuring fluorine.

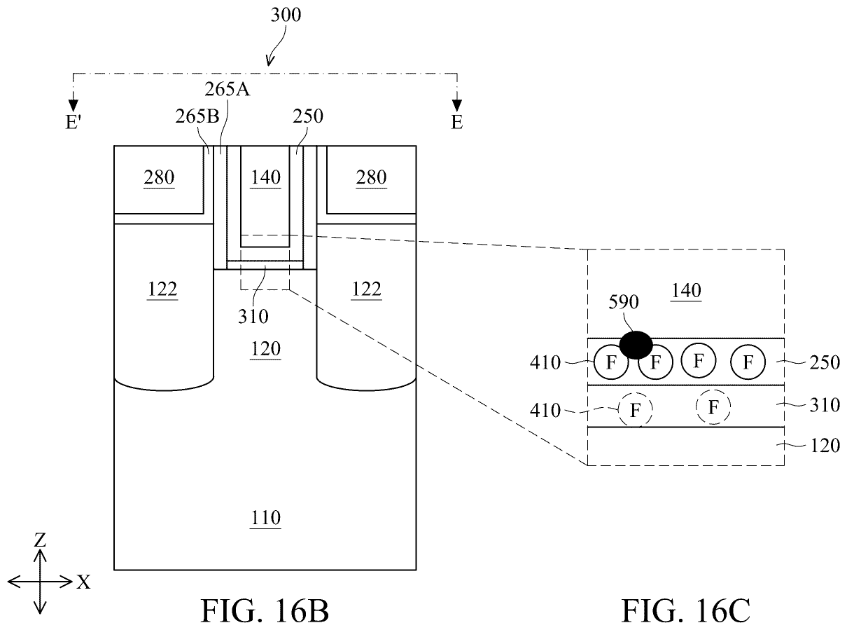

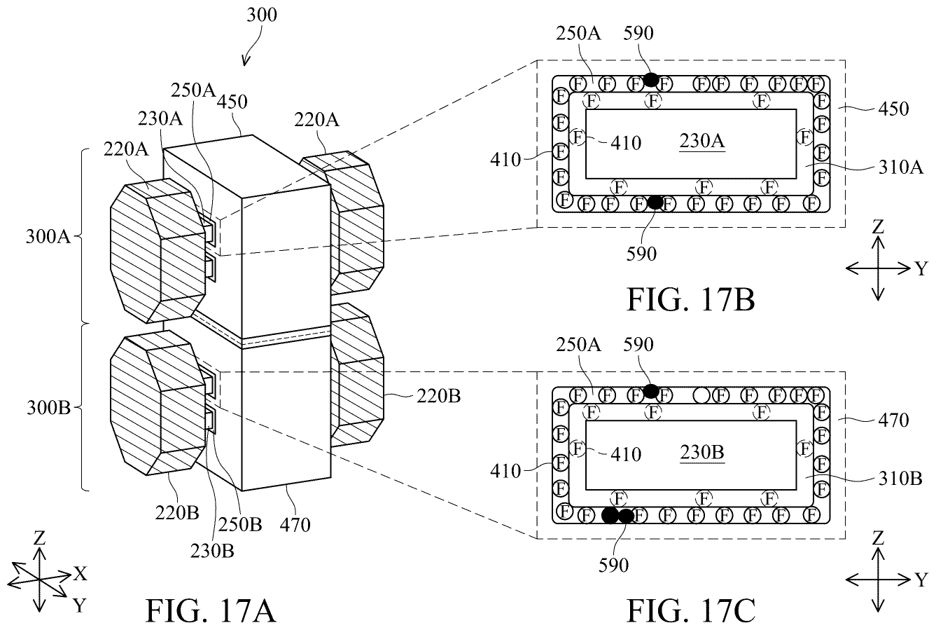

The above process flow describes embodiments of the present disclosure where a GAA device is implemented as the IC device 300. However, the concepts of the present disclosure may apply to other types of IC devices as well, such as FinFET devices and Complementary Field-Effect Transistors (CFETs). In that regard, FIGS. 16A-16C illustrate an embodiment of the IC device 300 that is implemented as a FinFET device, and FIGS. 17-17C illustrate an embodiment of the IC device 300 that is implemented as a CFET device.

In more detail, FIG. 16A illustrates a diagrammatic fragmentary three-dimensional perspective view of the IC device 300 implemented as a FinFET device, FIG. 16B illustrates a diagrammatic fragmentary cross-sectional side view of an IC device 300, and FIG. 16C illustrates a diagrammatic fragmentary cross-sectional side view of a magnified portion of the IC device 300. The cross-sectional side views of FIGS. 16B and 16C are each taken along a vertical plane (along a cutline E-E′) defined by the X-direction horizontally and the Z-direction vertically, and thus they are X-cut views. For reasons of consistency and clarity, similar components appearing in FIGS. 16A-16C and the previous figures will be labeled the same.

As shown in FIGS. 16A-16B, the FinFET embodiment of the IC device 300 includes semiconductive fin structures 120 (e.g., as active regions) that each protrude vertically upwards out of the substrate 110. Source/drain components 122 may be epitaxially grown on each of the semiconductive fin structures 120. In some embodiments, the source/drain components 112 may each include multiple layers, where at least two layers in the multiple layers contain the same semiconductor material with different concentrations (e.g., dopant profile variation).

Metal-containing gate electrodes 140 (which may include one or more WF metal layers and a fill metal, such as the fill metal component 510 discussed above) may be formed over the semiconductive fin structures 120, for example, by wrapping around the top and side surfaces of the semiconductive fin structures 120. In addition, an outermost surface of the metal-containing gate electrode 140 along the direction in which the gate is oriented (e.g., the Y-direction of FIG. 16A) may be non-linear (e.g., it may have various degrees of curvature). In some embodiments, the topmost surface of the metal-containing gate electrode 140 may be non-planar, and the metal-containing gate electrode may also have a seam, though these characteristics are not specifically illustrated in FIG. 16A for reasons of simplicity.

The gate dielectric layers 250 are disposed around the metal-containing gate electrodes 140. In a top view plane defined by the X-direction and the Y-direction, the gate dielectric layer 250 circumferentially surrounds the metal-containing gate electrode 140, which is also evident in FIG. 16A. In the cross-sectional side view of FIG. 16B, the gate dielectric layer 250 defines a recess in which the metal-containing gate electrode 140 is located. Gate spacers 265A (as a part of the dielectric materials 265 discussed above) may be disposed on opposite sides of the gate structure that includes the metal-containing gate electrode 140 and the gate dielectric layer 250. For example, the side surfaces of the gate spacers 265A are disposed on side surfaces of the gate dielectric layer 250. The gate spacers 265A are also in direct contact with a contact-etching stop layer (CESL) 265B (another part of the dielectric materials 265 discussed above). The CESL 265B are also located on the source/drain components 122 and on an upper surface of the isolation structure 130 that separates the semiconductive fin structures 120 in the Y-direction. The ILD 280 is located over the CESL 265B and surrounds the source/drain components 122 as well.

The magnified view of FIG. 16C corresponds to a portion of the IC device 300 that includes portions of the semiconductive fin structure 120, the interfacial layer 310, the gate dielectric layer 250, and the metal-containing gate electrode 140. The portion of the metal-containing gate electrode 140 illustrated in FIG. 16C may include an N-type WF metal layer or a P-type WF metal layer. As shown in FIG. 16C, fluorine atoms 410 are also disposed within the gate dielectric layer 250 and the interfacial layer 310. This is an inherent result of the performance of the unique fabrication process flow of the present disclosure. For example, a base layer similar to the base layer 350 discussed above may be formed on the gate dielectric layer 250, and a fluorine-containing layer similar to the fluorine-containing layer 370 discussed above may be formed on the base layer. An annealing process similar to the annealing process 400 discussed above may then be performed to drive the fluorine dopants from the fluorine-containing layer into the gate dielectric layer 250 and possibly into the interfacial layer 310. Thereafter, the fluorine-containing layer and the base layer may be removed, for example, using one or more wet etching or dry etching processes. After the removal of the fluorine-containing layer and the base layer, the metal-containing gate electrode 140 may be formed on the now fluorine-containing gate dielectric layer 250. Since the metal-containing gate electrode 140 is formed after fluorine has been driven into the gate dielectric layer 250, the metal-containing gate electrode 140 is substantially free of the fluorine atoms 410. Inside the gate dielectric layer 250 and/or the interfacial layer 310, the concentration of fluorine atoms 410 may follow a similar distribution discussed above. For example, the average concentration of fluorine is greater in the gate dielectric layer 250 than the interfacial layer 310. Within the gate dielectric layer 250, the fluorine concentration may vary as a function of depth, such that the concentration is greater near the interface with the metal-containing gate electrode 140 and lower near the interface with the interfacial layer 310. In addition, as was the case in the GAA implementation, intermix compounds 590 may be found within the gate dielectric layers 250. Again, the presence of fluorine in the gate dielectric layer 250 may reduce the MBE discussed above.

Referring now to FIGS. 17A-17C, FIG. 17A illustrates a diagrammatic fragmentary three-dimensional perspective view of the IC device 300 implemented as a CFET device, FIG. 17B illustrates a magnified diagrammatic fragmentary cross-sectional side view of an IC device 300, and FIG. 16C illustrates a magnified diagrammatic fragmentary cross-sectional side view of another portion of the IC device 300. The cross-sectional side views of FIGS. 17B and 17C are Y-cut views. For reasons of consistency and clarity, similar components appearing in FIGS. 17A-17C and the previous figures will be labeled the same.

As shown in FIG. 17A, the CFET embodiment of the IC device 300 includes an upper device 300A and a lower device 300B. The upper device 300A and the lower device 300B are connected together via an isolation layer 595. The upper device 300A includes a stack of upper nano-structure channels 230A (e.g., containing a semiconductor material such as silicon), upper gate dielectric layers 250A that circumferentially surround each of the upper nano-structure channels 230A, an upper gate electrode 450 that circumferentially surrounds the upper gate dielectric layers 250A, and upper source/drain components 220A that are disposed on opposite sides of the upper gate electrode 450 and connected together by the upper nano-structure channels 230A. In some embodiments, the upper gate electrode 450 includes P-type WF metals.

Similarly, the lower device 300B includes a stack of lower nano-structure channels 230B (e.g., containing a semiconductor material such as silicon), lower gate dielectric layers 250B that circumferentially surround each of the lower nano-structure channels 230B, a lower gate electrode 470 that circumferentially surrounds the lower gate dielectric layers 250B, and lower source/drain components 220B that are disposed on opposite sides of the lower gate electrode 470 and connected together by the lower nano-structure channels 230B. In some embodiments, the lower gate electrode 470 includes N-type WF metals.

The cross-sectional side view of FIG. 17B illustrates a magnified portion of the upper device 300A that includes portions of the upper nano-structure channel 230A, an upper interfacial layer 310A, the upper gate dielectric layer 250A, and the upper gate electrode 450. Meanwhile, the cross-sectional side view of FIG. 17C illustrates a magnified portion of the lower device 300B that includes portions of the lower nano-structure channel 230B, a lower interfacial layer 310B, the lower gate dielectric layer 250B, and the lower gate electrode 470. Similar to the GAA implementation discussed above, fluorine atoms 410 have been driven into the upper gate dielectric layer 250A and the lower gate dielectric layer 250B, as well as into the upper interfacial layer 310A and the lower interfacial layer 310B. The fluorine atoms 410 are dispersed throughout different segments of the upper/lower gate dielectric layers 250A/250B, including in the segments located directly above or below the upper and lower nano-structure channels 230A and 230B. The same is true for the distribution of the fluorine atoms 410 in the upper and lower interfacial layers 310A and 310B, but with lower fluorine concentration levels compared to the gate dielectric layers. The upper gate electrode 450 and the lower gate electrode 470 are each free of the fluorine atoms 410.

As discussed above in association with the GAA implementation of the IC device 300, the implementation of fluorine atoms 410 in the gate dielectric layers 250A/250B and interfacial layers 310A/310B, but not in the gate electrodes 450/470, is an inherent result of the performance of the unique fabrication process flow of the present disclosure. For example, base layers similar to the base layer 350 discussed above may be formed on the gate dielectric layers 250A/250B, and fluorine-containing layers similar to the fluorine-containing layer 370 discussed above may be formed on the base layers. An annealing process similar to the annealing process 400 discussed above may then be performed to drive the fluorine dopants from the fluorine-containing layers into the gate dielectric layers 250A/250B and possibly into the interfacial layers 310A/310B. Thereafter, the fluorine-containing layers and the base layers may be removed, for example, using one or more wet etching or dry etching processes. After the removal of the fluorine-containing layers and the base layers, the upper gate electrode 450 and the lower gate electrode 470 may be formed on the now fluorine-containing upper gate dielectric layer 250A and lower gate dielectric layer 250B, respectively. Since the upper gate electrode 450 and the lower gate electrode 470 are formed after fluorine has been driven into the gate dielectric layers 250A/250B, the upper electrode 450 and the lower gate electrode 470 are substantially free of the fluorine atoms 410. In addition, as was the case in the GAA implementation, the fluorine concentration level within each of the gate dielectric layers 250A/250B may vary as a function of depth (e.g., decrease as it gets closer to the nano-structure channel 230A/230B), and intermix compounds 590 may be found within the gate dielectric layers 250A/250B. Again, the presence of fluorine in the gate dielectric layers 250A/250B may reduce the MBE discussed above.

Regardless of whether the IC device is implemented as a GAA device, a FinFET device, or a CFET device, it is understood that additional fabrication processes may be performed to complete the fabrication of the IC device 300. For example, additional interconnection elements from additional interconnect layers of a multi-layer interconnect structure may be formed over the portion of the IC device 300. Such a multi-layer interconnect structure may be formed over the source/drain vias 550 and the gate contact 560 discussed above (see FIGS. 14A and 15A), and it may be used to provide electrical connectivity to the various components of the IC device 300 discussed above.

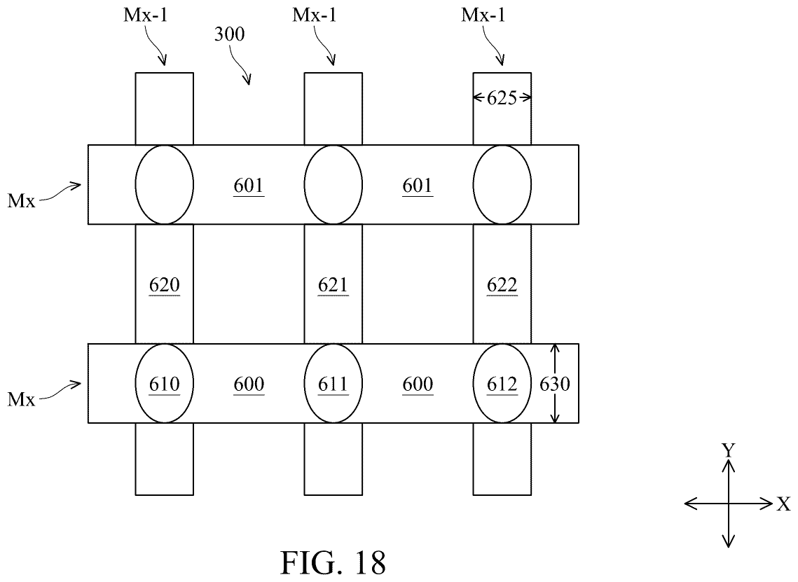

One example of such a multi-layer interconnect structure is illustrated in FIG. 18, which is a diagrammatic fragmentary planar top view of the IC device 300, at a stage of fabrication subsequent to the stage of fabrication illustrated in FIGS. 15A-15D. As shown in FIG. 18, interconnection elements 600 and 601 are formed directly over the conductive vias 610-612. The interconnection elements 600 and 601 are formed as a part of an interconnect layer M_{X}, which is one interconnect layer above the interconnect layer M_{X-1} that includes interconnection elements 620-622. Note that the interconnect layer M_{X-1} and the interconnect layer M_{X} can be any two vertically adjacent interconnect layers. For example, the interconnect layer M_{X-1} may be a metal-0 layer, while the interconnect layer M_{X} may be a metal-1 layer. Alternatively, the interconnect layer M_{X-1} may be a metal-3 layer, while the interconnect layer M_{X} may be a metal-4 layer.

Regardless of the exact interconnect layers to which the interconnection elements 620-622 and/or the interconnection elements 600-601 belong, it is understood that the interconnect layer M_{X-1} and the interconnect layer M_{X} may be interconnected by the conductive vias 610-612. For example, since the conductive via 610 is located in an overlap area between the interconnection element 620 and the interconnection element 600 in the planar top view, the conductive via 610 is electrically interconnected to both the interconnection element 620 and the interconnection element 600, such that a bottom surface (in the vertical Z-direction) of the conductive via 610 is in direct contact with the top surface of the interconnection element 620, and a top surface (in the vertical Z-direction) of the conductive via 610 is in direct contact with the bottom surface of the interconnection element 600.

In some embodiments, the interconnection elements 620-622 have widths that are different from the interconnection elements 600-601. For example, the interconnection elements 620-622 may each have a width 625 measured in the X-direction, while the interconnection elements 600-601 may each have a width 630 that is measured in the Y-direction, where the width 630 is greater than the width 625. In some embodiments, the width 625 may be in a range between about 0.01 microns and about 0.36 microns, and the width 630 may be in a range between about 0.01 microns and about 0.36 microns, but a ratio between the width 630 and the width 625 is greater than about 1:1. In other embodiments, the width 625 and the width 630 may be substantially equal to one another, and the ratio between the width 625 and the width 630 may be about 1:1.

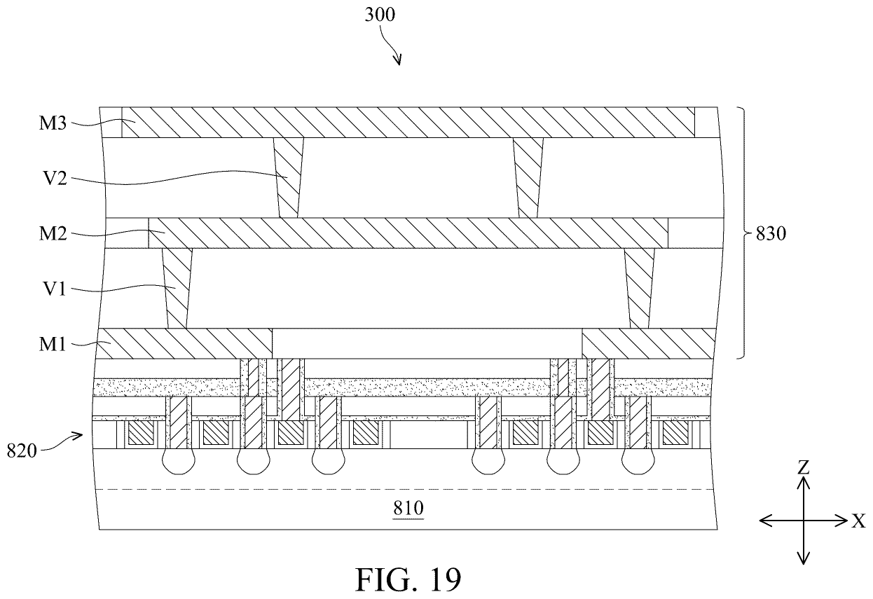

FIG. 19 is a diagrammatic fragmentary cross-sectional side view of an embodiment of the IC device 300 as an X-cut in an example context. In more detail, the IC device 300 includes a substrate 810, which may be an embodiment of the substrate 110 discussed above. A plurality of transistors 820, such as the FinFET, GAA, or CFET devices discussed above, may be formed in or on the substrate 810. An interconnect structure 830 is formed over the transistors 820 and provides electrical connectivity for the transistors 820. The interconnect structure 830 includes a plurality of interconnect layers, such as interconnect layers M1, M2, and M3. The interconnect structure 830 also includes a plurality of conductive vias to electrically couple the interconnect layers together. For example, a conductive via V1 electrically couples together interconnection features of the interconnect layers M1 and M2, and a conductive via V2 electrically couples together interconnection features of the interconnect layers M2 and M3. The interconnection features may include metal lines (e.g., in the form of rectangular strips that extend in a horizontal direction). In some embodiments, a thickness of a bottommost one of the plurality of metal lines (e.g., located in a bottommost interconnect layer) is less than a thickness of at least one of the plurality of metal lines disposed above the bottommost one of the plurality of metal lines, and at least one of the plurality of metal lines comprises a curved end portion. Using FIG. 18 as an example, at least one of the interconnection elements 600-601 and 620-622 comprises a curved end portion. In addition, at least two metal lines in the interconnect layers extend along different directions. For example, a metal line in an M1 layer may extend in one horizontal direction, while a metal line in an M2 layer (e.g., disposed immediately above the M1 layer) may extend in another horizontal direction different from (e.g., perpendicular to) the horizontal direction in which the metal line in M1 layer extends. Using FIG. 18 as an example again, the interconnection element 620-622 in the M_{X-1} layer each extend in the Y-direction, whereas the interconnection elements 600-601 in the M_{X} layer each extend in the X-direction. Furthermore, although only three interconnect layers M1-M3 are illustrated in the embodiment of FIG. 19, this is merely done for the sake of simplicity. It is understood that the interconnect structure 830 may include many more interconnect layers (or fewer) in other embodiments, and that the selective enlargement of the conductive vias may apply to any conductive via interconnect any two adjacent (in the vertical direction) interconnect layers in the interconnect structure 830.

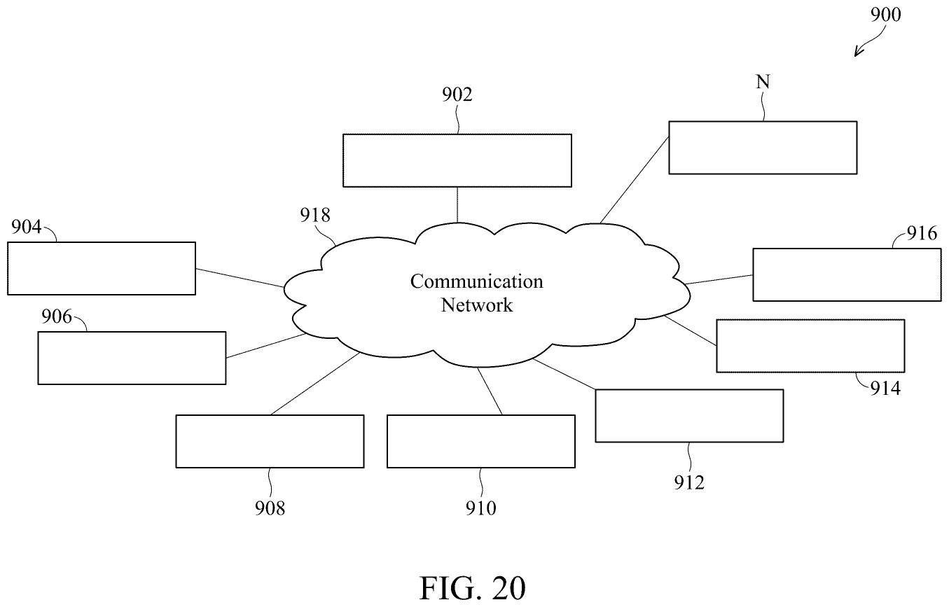

FIG. 20 illustrates an integrated circuit fabrication system 900 that may be used to perform the fabrication processes discussed above (e.g., the deposition processes for forming the seed and fluorine-containing layers, the annealing process used to drive the fluorine into the gate dielectric layers, the etching processes used to remove the seed and fluorine-containing layers, the CMP processes used to planarize surfaces, etc.) according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform various lithography processes; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

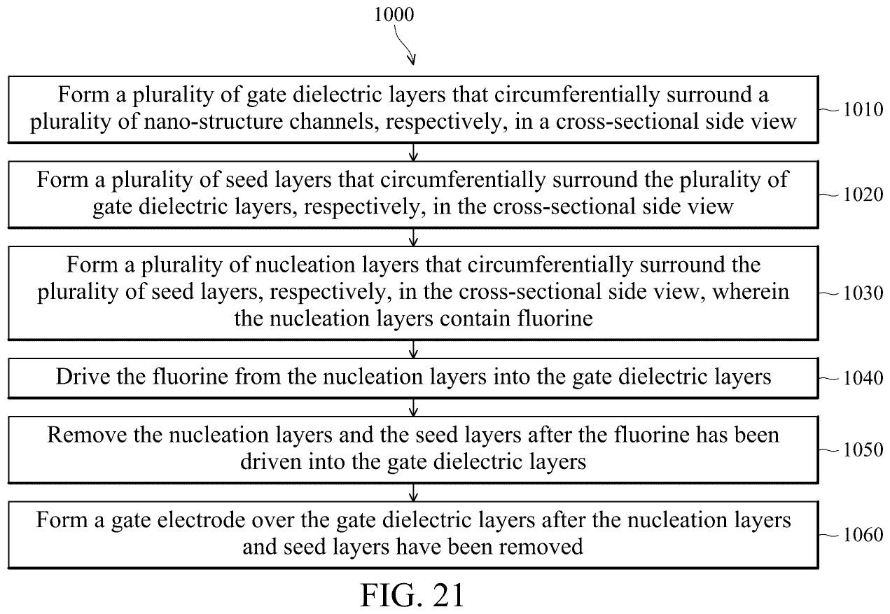

FIG. 21 is a flowchart of a method 1000 of bonding IC devices according to various aspects of the present disclosure. The method 1000 includes a step 1010 to form a plurality of gate dielectric layers that circumferentially surround a plurality of nano-structure channels, respectively, in a cross-sectional side view.

The method 1000 includes a step 1020 to form a plurality of base layers that circumferentially surround the plurality of gate dielectric layers, respectively, in the cross-sectional side view. In some embodiments, the step 1020 includes depositing, via an atomic layer deposition (ALD) process, a titanium nitride material, a tantalum nitride material, or a titanium silicon nitride material as the base layers.

The method 1000 includes a step 1030 to form a plurality of fluorine-containing layers that circumferentially surround the plurality of base layers, respectively, in the cross-sectional side view. The fluorine-containing layers contain fluorine. In some embodiments, the step 1030 includes depositing a tungsten-containing material as the fluorine-containing layer. In some embodiments, the ALD process is performed using WF₆ as a precursor and B₂H₆ as a reaction gas. In some embodiments, the fluorine-containing layers are formed to have a greater thicknesses than the base layers. Note that since B₂H₆ may be used as a reaction gas, a small amount of boron may also diffuse into the gate dielectric layer.

The method 1000 includes a step 1040 to drive the fluorine from the fluorine-containing layers into the gate dielectric layers. In some embodiments, the fluorine is driven from the fluorine-containing layers into the gate dielectric layers via an annealing process. In some embodiments, the annealing process is performed in a temperature range between about 450 degrees Celsius and about 550 degrees Celsius and for a period between about 10 seconds and about 30 seconds.

The method 1000 includes a step 1050 to remove the fluorine-containing layers and the base layers after the fluorine has been driven into the gate dielectric layers. In some embodiments, the fluorine-containing layers and the base layers are removed via one or more etching processes.

The method 1000 includes a step 1060 to form a gate electrode over the gate dielectric layers after the fluorine-containing layers and base layers have been removed.

It is understood that the method 1000 may include further steps performed before, during, or after the steps 1010-1060. For example, the method 1000 may include a step of forming a plurality of interfacial layers that circumferentially surround the plurality of nano-structure channels, respectively, in the cross-sectional side view. The gate dielectric layers are formed to each circumferentially surround a respective one of the interfacial layers in the cross-sectional side view. In some embodiments, the annealing process of the step 1040 further causes the fluorine to be driven into the interfacial layers. For reasons of simplicity, other additional steps are not discussed herein in detail.

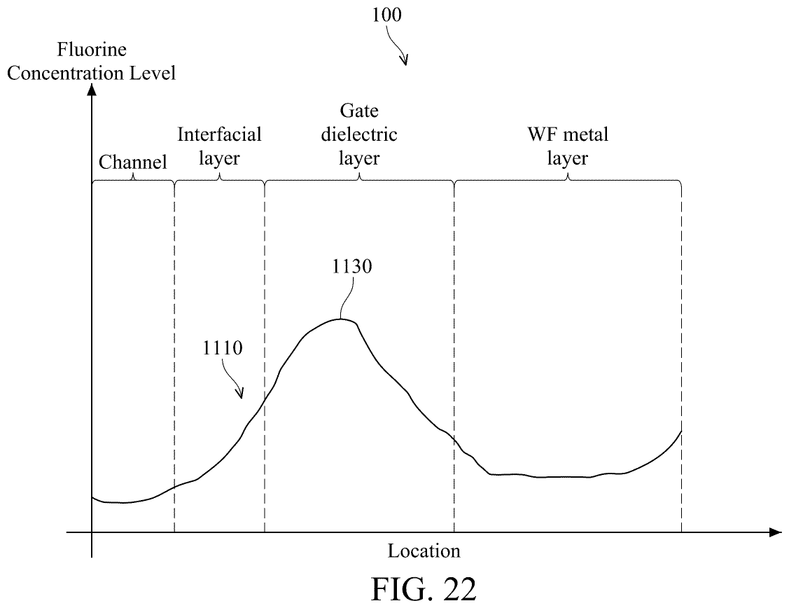

FIG. 22 is a graph 1100 illustrating a fluorine distribution profile according to various aspects of the present disclosure. In more detail, the graph 1100 illustrates a plot 1110 that represents the distribution of fluorine at different locations of an IC device, such as the GAA device, FinFET device, or the CFET device discussed above. The plot 1110 has a horizontal axis component and a vertical axis component. The horizontal axis component represents the location within the IC device. For example, the horizontal axis is divided into a plurality of regions that include: a channel region (e.g., one of the nano-structure channels 230 discussed above), an interfacial layer region (e.g., one of the interfacial layers 310 formed on the nano-structure channel 230), a gate dielectric layer region (e.g., one of the gate dielectric layers 250 formed on the interfacial layer 310), and a WF metal layer region (e.g., the P-type WF metal layer 450 in some embodiments, or the N-type WF metal layer 470 in some other embodiments). Meanwhile, the vertical axis represents a fluorine concentration level at any given point within the IC device. As such, the plot 1110 demonstrates how the fluorine concentration level varies within different regions of the IC device, which is one of the unique characteristics of the IC device fabricated according to the process flow of the present disclosure.

In more detail, the fluorine concentration level is relatively low at the channel region, but it starts to rise within the interfacial layer region. The fluorine concentration level continues to rise within the gate dielectric layer region, until a peak concentration level 1130 is reached. The peak concentration level 1130 may occur near a midpoint of the gate dielectric layer region. In some embodiments, the peak concentration level 1130 may occur at or shortly before the midpoint of the gate dielectric layer region is reached. In some other embodiments, the peak concentration level 1130 may occur at or shortly after the midpoint of the gate dielectric layer region is reached. For example, suppose that a total thickness of the gate dielectric layer region is represented by T, the peak concentration level 1130 may occur at a distance that is 0.1×T within (e.g., either before or after) the midpoint of the gate dielectric layer region. In any case, after reaching the peak concentration level 1130, the fluorine concentration level begins to gradually decline within the gate dielectric layer region, as well as into the WF metal layer region. It is noted that the fluorine concentration level may begin to rise slightly toward a boundary of the WF metal layer region opposite the interface with the gate dielectric layer region, though the fluorine concentration level within the WF metal layer region is still far below the fluorine concentration level within the gate dielectric layer region, either in terms of their respective peaks, or in terms of their respective average levels. It is also noted that the fluorine concentration level at an interface between the interfacial layer region and the gate dielectric layer region is greater than the fluorine concentration level at an interface between the gate dielectric layer region and the WF metal layer region.

The fluorine distribution shown in FIG. 22 illustrates one of the unique physical characteristics of the IC device according to the present disclosure, which is an inherent result of the unique fabrication process flow discussed above that was used to fabricate the IC device of the present disclosure. In that regard, one of the unique aspects of the fabrication process flow herein pertains to how fluorine is incorporated into the gate dielectric layer 250 (and/or the interfacial layer 310). Specifically, the fluorine-containing layer 370 is formed to circumferentially surround the gate dielectric layer 250 (which itself is formed to circumferentially surround the interfacial layer 310) before the formation of the WF metal layers. In this manner, the fluorine is driven (e.g., by the annealing process 400) mostly into the gate dielectric layer 250, and then into the interfacial layer 310 next (because the interfacial layer 310 is separated from the fluorine-containing layer 370 by the gate dielectric layer 250). An even a smaller amount is driven into the nano-structure channel 230, because the nano-structure channel 230 is separated from the fluorine-containing layer 370 by both the interfacial layer 310 and the gate dielectric layer 250. And since the WF metal layer 450 or 470 is formed after the fluorine has been driven into the gate dielectric layer 250 and into the interfacial layer 310, just a small amount of the fluorine may exist in the WF metal layer 450 or 470, which may be a result of the fluorine diffusing from the gate dielectric layer 250 into the WF metal layer 450 or 470. This is why the fluorine content in the gate dielectric layer 250 is significantly greater than the fluorine content in the WF metal layer 450 or 470, as shown in the graph 1100. In comparison, IC devices fabricated according to other schemes may involve the fluorine diffusing from the WF metal layer into the gate dielectric layer (and/or into the interfacial layer). Consequently, the fluorine content is higher in the WF metal layers than in the gate dielectric layer or interfacial layer according to IC devices not fabricated according to the various embodiments of the present disclosure.

In summary, the present disclosure involves incorporating fluorine into a gate dielectric layer. For example, a base layer (e.g., containing TiN, TSN, or TaN) is formed circumferentially around the gate dielectric layer, and a fluorine-containing layer is formed circumferentially around the base layer. The fluorine-containing layer may contain tungsten and fluorine. An annealing process is performed to drive the fluorine from the fluorine-containing layer into the gate dielectric layer (and possibly into the interfacial layer that is underneath the gate dielectric layer). Thereafter, the fluorine-containing layer and the base layer are removed, for example, using one or more etching processes. Work function metal layers are then formed on the gate dielectric layer (now containing fluorine) after the removal of the fluorine-containing layer and base layer.

The embodiments of the present disclosure offer advantages over conventional IC devices. It is understood, however, that other embodiments may offer additional advantages, and not all advantages are necessarily disclosed herein, and that no particular advantage is required for all embodiments. One advantage is improved device performance. For example, as semiconductor device sizes continue to shrink, it may be difficult to incorporate fluorine into portions of the gate dielectric layer that are located directly above or below a nano-structure channel. Here, the unique fabrication process flow of the present disclosure allows the fluorine to be incorporated into different segments of the gate dielectric layer, including the segments that are disposed directly above or below the nano-structure channel. Such a distribution profile of the fluorine increases an energy barrier needed for metals to diffuse between adjacent transistors (e.g., from NFET to PFET). For example, fluorine incorporated into the gate dielectric layers may reduce defects by reducing dangling bonds and/or oxygen vacancies, which in turn increases the energy barrier and reduces the metal boundary effect (MBE). Since the metal diffusion would otherwise cause unintended shifts in threshold voltages of the NFET or PFET, the reduction of the metal diffusion herein allows the transistors to maintain their intended threshold voltages and reduce leakage current, thereby improving device performance and/or yield. Other advantages include compatibility with existing fabrication processes and the ease and low cost of implementation.

One aspect of the present disclosure pertains to a device. The device includes a stack of nano-structure channels disposed over one another in a vertical direction in a cross-sectional side view defined by the vertical direction and a first horizontal direction. Each of the nano-structure channels contains silicon. For each of the nano-structure channels, a length thereof measured in a second horizontal direction different from the first horizontal direction is greater than a thickness thereof measured in the vertical direction. A plurality of gate dielectric layers is disposed over the stack of the nano-structure channels. Each of the gate dielectric layers circumferentially surrounds a respective one of the nano-structure channels in the cross-sectional side view. Fluorine is disposed within each of the gate dielectric layers, including in portions of the gate dielectric layers disposed directly above or below the nano-structure channels in the cross-sectional side view. A gate electrode structure is disposed over the gate dielectric layers.

Another aspect of the present disclosure pertains to a method. A plurality of source/drain components and a plurality of nano-structure channels between the plurality of source/drain components are formed. At least one of the source/drain components include multiple layers that contain a same semiconductor material with different dopant concentrations. A plurality of gate dielectric layers of a gate structure is formed around the plurality of nano-structure channels. A plurality of first layers is formed around the plurality of gate dielectric layers. The first layers contain titanium nitride, tantalum nitride, or titanium silicon nitride. A plurality of second layers is formed around the plurality of first layers. The second layers contain fluorine. An annealing process is performed. The annealing process causes the fluorine to migrate from the second layers to the gate dielectric layers. The second layers and the first layers are removed after the annealing process has been performed. A gate electrode of the gate structure is formed over the gate dielectric layers after the removing of the second layers and the first layers. The gate electrode contains at least one metal layer. An interlayer dielectric is formed over the gate electrode. The gate dielectric layers have a higher dielectric constant value than the interlayer dielectric. A gate contact is formed that extends through the interlayer dielectric. The gate contact is electrically coupled to the gate electrode.

Yet another aspect of the present disclosure pertains to a method. According to the method, a plurality of nano-structure channels is formed over a semiconductor fin structure in a cross-sectional side view. The semiconductor fin structure is surrounded by an isolation structure in the cross-sectional side view. A plurality of gate dielectric layers of a gate structure is formed that circumferentially surrounds the plurality of nano-structure channels, respectively. Portions of the gate dielectric layer extend along a top surface of the isolation structure in the cross-sectional side view. A plurality of base layers is formed that circumferentially surround the plurality of gate dielectric layers, respectively, in the cross-sectional side view. A plurality of fluorine-containing layers is formed that circumferentially surround the plurality of base layers, respectively, in the cross-sectional side view. The fluorine-containing layers contain fluorine. The fluorine is driven from the fluorine-containing layers into the gate dielectric layers. The fluorine-containing layers and the base layers are removed after the fluorine has been driven into the gate dielectric layers. A gate electrode of the gate structure is formed over the gate dielectric layers after the fluorine-containing layers and base layers have been removed. The gate electrode contains at least one metal layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a stack of nano-structure channels disposed over one another in a vertical direction in a cross-sectional side view defined by the vertical direction and a first horizontal direction, wherein the nano-structure channels contain silicon;
a plurality of gate dielectric layers of a gate structure disposed over the stack of the nano-structure channels, wherein the gate dielectric layers circumferentially surround respective ones of the nano-structure channels in the cross-sectional side view, and wherein one of the gate dielectric layers has a first fluorine concentration level; and
a gate electrode structure of the gate structure disposed over the gate dielectric layers, wherein the gate electrode structure include a work function metal, and wherein the work function metal has a second fluorine concentration level that is lower than the first fluorine concentration level;
wherein in a top view defined by the first horizontal direction and a second horizontal direction different from the first horizontal direction, the gate electrode structure extends in the first horizontal direction, and at least one of the nano-structure channels extends in the second horizontal direction.

2. The device of claim 1, wherein:
a first gate dielectric layer of the plurality of gate dielectric layers circumferentially surrounds a first nano-structure channel of the stack of nano-structure channels in the cross-sectional side view;
a first segment of the first gate dielectric layer disposed directly above or below the first nano-structure channel in the cross-sectional side view has a first average concentration level of fluorine;
a second segment of the first gate dielectric layer disposed beside the first nano-structure channel laterally in the cross-sectional side view has a second average concentration level of fluorine; and
a ratio of the first average concentration level of fluorine and the second average concentration level of fluorine is in a range between about 0.8:1 and about 1.2:1.

3. The device of claim 1, wherein an average concentration level of fluorine within one of the gate dielectric layers is greater than an average concentration level of fluorine within the work function metal.

4. The device of claim 1, wherein a peak concentration level of fluorine within the device occurs at or near a midpoint within one of the gate dielectric layers.

5. The device of claim 1, further comprising a plurality of interfacial layers, wherein:
each of the interfacial layers circumferentially surrounds a respective one of the nano-structure channels and is circumferentially surrounded by a respective one of the gate dielectric layers in the cross-sectional side view; and
fluorine is disposed within each of the interfacial layers, including in portions of the interfacial layers disposed directly above or below the nano-structure channels in the cross-sectional side view.

6. The device of claim 5, wherein an average concentration level of fluorine within each of the interfacial layers is less than an average concentration level of fluorine within each of the gate dielectric layers.

7. The device of claim 1, wherein titanium, silicon, tantalum, or boron is disposed within each of the gate dielectric layers, including in portions of the gate dielectric layers disposed directly above or below the nano-structure channels in the cross-sectional side view.

8. The device of claim 7, wherein an average concentration level of titanium, silicon, or tantalum is less than an average concentration level of fluorine within each of the gate dielectric layers.

9. The device of claim 1, wherein within one of the gate dielectric layers, a distribution of fluorine is substantially uniform among a portion of the gate dielectric layer disposed above the nano-structure channel, a portion of the gate dielectric layer disposed below the nano-structure channel, and a portion of the gate dielectric layer disposed on a side surface of the nano-structure channel.

10. A method, comprising:
forming a plurality of source/drain components and a plurality of nano-structure channels between the plurality of source/drain components, wherein at least one of the source/drain components include multiple layers that contain a same semiconductor material with different dopant concentrations;
forming a plurality of gate dielectric layers of a gate structure around the plurality of nano-structure channels;
forming a plurality of first layers around the plurality of gate dielectric layers, wherein the first layers contain titanium nitride, tantalum nitride, or titanium silicon nitride;
forming a plurality of second layers around the plurality of first layers, wherein the second layers contain fluorine;
performing an annealing process, wherein the annealing process causes the fluorine to migrate from the second layers to the gate dielectric layers;
removing the second layers and the first layers after the annealing process has been performed;
forming a gate electrode of the gate structure over the gate dielectric layers after the removing, wherein the gate electrode contains at least one metal layer;
forming an interlayer dielectric over the gate electrode, wherein the gate dielectric layers have a higher dielectric constant value than the interlayer dielectric; and
forming a gate contact that extends through the interlayer dielectric, wherein the gate contact is electrically coupled to the gate electrode.

11. The method of claim 10, wherein the second layers are formed using tungsten hexafluoride (WF₆) as a precursor and diborane (B₂H₆) as a reaction gas.

12. The method of claim 10, wherein at least one of the second layers is formed to have a greater thickness than at least one of the first layers.

13. A method, comprising:
forming a plurality of nano-structure channels over a semiconductor fin structure in a cross-sectional side view, wherein the semiconductor fin structure is surrounded by an isolation structure in the cross-sectional side view;
forming a plurality of gate dielectric layers of a gate structure that circumferentially surrounds the plurality of nano-structure channels, respectively, wherein portions of the gate dielectric layer extend along a top surface of the isolation structure in the cross-sectional side view;
forming a plurality of base layers that circumferentially surround the plurality of gate dielectric layers, respectively, in the cross-sectional side view;
forming a plurality of fluorine-containing layers that circumferentially surround the plurality of base layers, respectively, in the cross-sectional side view, wherein the fluorine-containing layers contain fluorine;
driving the fluorine from the fluorine-containing layers into the gate dielectric layers;
removing the fluorine-containing layers and the base layers after the fluorine has been driven into the gate dielectric layers; and
forming a gate electrode of the gate structure over the gate dielectric layers after the fluorine-containing layers and base layers have been removed, wherein the gate electrode contains at least one metal layer.

14. The method of claim 13, wherein the forming the plurality of base layers comprises depositing a titanium nitride material, a tantalum nitride material, or a titanium silicon nitride material as the base layers.

15. The method of claim 13, wherein the fluorine-containing layers are formed via a deposition process, and wherein the fluorine-containing layers further contain tungsten.

16. The method of claim 15, wherein the deposition process is performed using WF₆ as a precursor and B₂H₆ as a reaction gas.

17. The method of claim 15, wherein each of the fluorine-containing layers is formed to have a greater thickness than each of the base layers.

18. The method of claim 13, wherein the fluorine is driven from the fluorine-containing layers into the gate dielectric layers via an annealing process.

19. The method of claim 18, wherein the annealing process is performed in a temperature range between about 450 degrees Celsius and about 550 degrees Celsius and for a period between about 10 seconds and about 30 seconds.

20. The method of claim 18, further comprising forming a plurality of interfacial layers that circumferentially surround the plurality of nano-structure channels, respectively, in the cross-sectional side view, wherein the gate dielectric layers are formed to each circumferentially surround a respective one of the interfacial layers in the cross-sectional side view, and wherein the annealing process further causes the fluorine to be driven into the interfacial layers.
